(19) United States
(12) Patent Application Publication
(10) Pub. No.: US 2011/0298097 A1
(43) Pub. Date: Dec. 8, 2011

(54) SEMICONDUCTOR DEVICE AND METHOD FOR MANUFACTURING THE SAME

(75) Inventors: Manabu Sueyoshi, Kanagawa (JP); Seiji Muranaka, Kanagawa (JP); Tomoryo Shono, Kanagawa (JP); Itaru Kanno, Kanagawa (JP)

(73) Assignee: Renesas Electronics Corporation

(21) Appl. No.: 13/156,021

(22) Filed: Jun. 8, 2011

(30) Foreign Application Priority Data
Jun. 8, 2010 (JP) 2010-130835

(51) Int. Cl. H01L 29/41; H01L 21/283

(52) U.S. Cl. 257/621; 438/667; 257/E21.159; 257/E29.112

(57) ABSTRACT

A semiconductor device is provided wherein stacked semiconductor substrates are electrically coupled together in a satisfactory state by a conductor buried in the interior of a through hole. A first semiconductor substrate includes a substrate having main surfaces, further includes a semiconductor element formed within and over the substrate, a wiring coupled to the semiconductor element electrically, and a conductive layer formed in the interior of a through hole, the through hole extending through mutually confronting first and second main surfaces as the main surfaces of the substrate and reaching the wiring. The first semiconductor substrate and a second semiconductor substrate are stacked and the conductive layer is coupled to a wiring of the second semiconductor substrate electrically. In a second main surface of the conductive layer, a recess is formed around an end portion of the through hole so that a bottom wall surface of the recess is present in the interior of the substrate. A conductive material which constitutes the conductive layer is filled in the interior of the recess.

### CROSS-REFERENCE TO RELATED APPLICATIONS

The disclosure of Japanese Patent Application No. 2010-130835 filed on Jun. 8, 2010 including the specification, drawings and abstract is incorporated herein by reference in its entirety.

### BACKGROUND

The present invention relates to a semiconductor device and a method for manufacturing the same. More specifically, the present invention is concerned with a semiconductor device having a multi-layer interconnection structure and a method for manufacturing the same.

With advance of microminiaturization such as, for example, reduction of the minimum width of wiring in semiconductor devices to 100 nm or smaller, the influence of RC (Resistance-Capacitance) delay in the multi-layer interconnection technique on device characteristics is becoming a serious problem. In stacking plural semiconductor chips each incorporating a large number of semiconductor devices, a wire bonding technique has heretofore been used as a method for coupling with for example external terminals electrically. However, in coupling by wire bonding, it is difficult to solve such a problem as the above RC delay.

In this connection, a through hole is formed in a substrate which constitutes a semiconductor chip and a conductor is buried into the through hole to form an electrode capable of electrically coupling together one main surface and an opposite main surface confronting each other of the substrate. There has been proposed TSV (Through-Si-Via) of the above configuration with a conductor buried in the through hole.

For example, in Japanese Unexamined Patent Publication No. 2009-158764 (Patent Document 1) there is disclosed a stacked type semiconductor device wherein semiconductor substrates each formed with TSV are stacked. In Patent Document 1, high-density dummy bumps (dummy TSVs) are formed at a peripheral portion with respect to a circuit area to suppress the inconvenience that a semiconductor substrate which has become thin forms chipping at the peripheral portion in the manufacturing process. In Patent Document 1 is found a disclosure to the effect that in the above configuration the dummy bumps and another wafer are bonded together with a high bonding force, resulting in the strength of the peripheral portion being enhanced and the occurrence of chipping reduced.

### SUMMARY

It is required that a TSV having good electrical characteristics and reliability be formed by filling the interior of a through hole with a conductor which through hole is formed in a silicon substrate. Electrolytic plating technique is mentioned as effective means for burying a conductor in the interior of TSV. More specifically, it is preferable that the burying of copper in the interior of TSV having a diameter of the order of 1 to 100 μm and a high aspect ratio (AR of 3 or more) when seen in plan be done stably and positively by electrolytic plating.

However, in case of burying a conductor in the interior of TSV, it is presumed that a pattern layout at a peripheral portion of the TSV pattern exerts a great influence on the performance of the conductor which is buried in the interior of TSV by electrolytic plating. No disclosure on this point is found in Patent Document 1. Therefore, the adherence of the interior conductor to TSV is likely to be deteriorated. As a result, the conductivity of the semiconductor device comprising stacked semiconductor substrates in question is likely to be deteriorated.

The present invention has been accomplished in view of the above-mentioned problem and it is an object of the present invention to provide a semiconductor device wherein stacked semiconductor substrates are coupled together in an electrically satisfactory manner through a conductor buried in the interior of a through hole, as well as a method for manufacturing the semiconductor device.

A semiconductor device including a plurality of stacked semiconductor substrates according to one aspect of the present invention has the following configuration. Of the semiconductor substrates, a first semiconductor substrate includes a substrate having main surfaces, a first semiconductor element formed within and over the substrate, a first wiring coupled to the first semiconductor element electrically, and a conductive layer formed in the interior of a through hole, the through hole extending through mutually confronting first and second main surfaces as the main surfaces of the substrate and reaching the first wiring. Of the semiconductor substrates, a second semiconductor substrate, which is directly stacked over the first semiconductor substrate, includes a second semiconductor element and a second wiring. The conductive layer is coupled to the second wiring of the second semiconductor substrate electrically. In the second main surface of the first semiconductor substrate, a recess is formed around an end portion of the through hole. A bottom wall surface of the recess is present in the interior of the substrate. A conductive material which constitutes the conductive layer is filled in the interior of the recess.

A method for manufacturing a semiconductor device according to another aspect of the present invention includes the following steps. First, there is provided a first semiconductor substrate, the first semiconductor substrate including a substrate having main surfaces, a first semiconductor element formed within and over the substrate, and a first wiring coupled to the first semiconductor element electrically. There are formed a through hole, the through hole extending through mutually confronting first and second main surfaces as the main surfaces of the substrate and reaching the first wiring, and a recess around an end portion of the through hole provided in the second main surface. A conductive layer is formed to fill the interior of the through hole and that of the recess. There is provided a second semiconductor substrate having a second semiconductor element and a second wiring. The first and second semiconductor substrates are stacked one over the other. The conductive layer and the second wiring of the second semiconductor substrate are coupled together electrically. A bottom wall surface of the recess is present in the interior of the substrate.

In the semiconductor device of the present invention, the filling of the conductor in the interior of the conductive layer can be done more uniformly by the recess formed around an end portion of the conductive layer extending through both first and second main surfaces of the semiconductor substrate. Accordingly, it is possible to provide a semiconductor device wherein the first and second semiconductor substrates stacked one over the other are rendered conducting each other by the conductive layer of high quality.

By using the semiconductor device manufacturing method according to the present invention, the conductive layer which fills up a through hole formed through both first and second main surfaces of the semiconductor substrate can be made more uniform by the recess formed around an end portion of the through hole. Accordingly, it is possible to provide a semiconductor device wherein the first and second semiconductor substrates are rendered conducting each other by the conductive layer of high quality.

### BRIEF DESCRIPTION OF THE DRAWINGS

FIG. 1 is a schematic sectional view showing the configuration of a semiconductor device according to a first embodiment of the present invention;

FIG. 2 is a schematic plan view showing the configuration of each semiconductor chip shown in FIG. 1;

FIG. 3 is a schematic plan view showing an example of a relation in shape and position between a conductive via and dummy vias formed around the conductive via;

FIG. 4 is an enlarged schematic plan view of an area IV enclosed with a dotted line in FIG. 3;

FIG. 5 is a schematic sectional view of a portion taken along line V-V in FIG. 3;

FIG. 6 is a schematic plan view showing a first modification of the relation in shape and position between a conductive via and dummy vias formed around the conductive via;

FIG. 7 is a schematic plan view showing a second modification of the relation in shape and position between a conductive via and dummy vias formed around the conductive via;

FIG. 8 is a schematic plan view showing a third modification of the relation in shape and position between a conductive via and dummy vias formed around the conductive via;

FIG. 9 is a schematic plan view showing a fourth modification of the relation in shape and position between a conductive via and dummy vias formed around the conductive via;

FIG. 10 is a schematic plan view showing a fifth modification of the relation in shape and position between a conductive via and dummy vias formed around the conductive via;

FIG. 11 is a schematic plan view showing a sixth modification of the relation in shape and position between a conductive via and dummy vias formed around the conductive via;

FIG. 12 is a schematic plan view showing a seventh modification of the relation in shape and position between a conductive via and dummy vias formed around the conductive via;

FIG. 13 is a schematic plan view showing an eighth modification of the relation in shape and position between a conductive via and dummy vias formed around the conductive via;

FIG. 14 is a schematic sectional view showing a first step in a semiconductor device manufacturing method according to the first embodiment;

FIG. 15 is a schematic sectional view showing a second step in the semiconductor device manufacturing method according to the first embodiment;

FIG. 16 is a schematic sectional view showing a third step in the semiconductor device manufacturing method according to the first embodiment;

FIG. 17 is a schematic sectional view showing a fourth step in the semiconductor device manufacturing method according to the first embodiment;

FIG. 18 is a schematic sectional view showing a fifth step in the semiconductor device manufacturing method according to the first embodiment;

FIG. 19 is a schematic sectional view showing a sixth step in the semiconductor device manufacturing method according to the first embodiment;

FIG. 20 is a schematic sectional view showing a seventh step in the semiconductor device manufacturing method according to the first embodiment;

FIG. 21 is a schematic sectional view showing an eighth step in the semiconductor device manufacturing method according to the first embodiment;

FIG. 22 is a schematic sectional view showing in detail a first step in a conductive via forming method according to the first embodiment;

FIG. 23 is a schematic sectional view showing in detail a second step in the conductive via forming method according to the first embodiment;

FIG. 24 is a schematic sectional view showing in detail a third step in the conductive via forming method according to the first embodiment;

FIG. 25 is a schematic sectional view showing in detail a fourth step in the conductive via forming method according to the first embodiment;

FIG. 26 is a schematic sectional view showing in detail a fifth step in the conductive via forming method according to the first embodiment;

FIG. 27 is a schematic sectional view showing in detail a sixth step in the conductive via forming method according to the first embodiment;

FIG. 28 is a schematic sectional view showing in detail a seventh step in the conductive via forming method according to the first embodiment;

FIG. 29 is a schematic sectional view showing in detail an eighth step in the conductive via forming method according to the first embodiment;

FIG. 30 is a schematic sectional view showing in detail a ninth step in the conductive via forming method according to the first embodiment;

FIG. 31 is a schematic sectional view showing the configuration of a conductive via not formed with dummy vias for comparison with the schematic sectional view of FIG. 5;

FIG. 32 is a schematic sectional view showing the configuration of a multi-layer interconnection structure of a semiconductor device for comparison with the schematic sectional view of FIG. 1;

FIG. 33 is a schematic sectional view showing a first step in a semiconductor device manufacturing method according to a second embodiment of the present invention;

FIG. 34 is a schematic sectional view showing a second step in the semiconductor device manufacturing method according to the second embodiment;

FIG. 35 is a schematic sectional view showing a third step in the semiconductor device manufacturing method according to the second embodiment;

FIG. 36 is a schematic sectional view showing a fourth step in the semiconductor manufacturing method according to the second embodiment;

FIG. 37 is a schematic sectional view showing a fifth step in the semiconductor device manufacturing method according to the second embodiment;

FIG. 38 is a schematic sectional view showing a sixth step in the semiconductor device manufacturing method according to the second embodiment;

FIG. 39 is a schematic sectional view showing a seventh step in the semiconductor device manufacturing method according to the second embodiment;

FIG. 40 is a schematic sectional view showing a first step in a semiconductor device manufacturing method according to a third embodiment of the present invention;

FIG. 41 is a schematic sectional view showing a second step in the semiconductor device manufacturing method according to the third embodiment;

FIG. 42 is a schematic sectional view showing a third step in the semiconductor device manufacturing method according to the third embodiment;

FIG. 43 is a schematic sectional view showing a fourth step in the semiconductor device manufacturing method according to the third embodiment;

FIG. 44 is a schematic sectional view showing a fifth step in the semiconductor device manufacturing method according to the third embodiment;

FIG. 45 is a schematic sectional view showing a sixth step in the semiconductor device manufacturing method according to the third embodiment; and

FIG. 46 is a schematic sectional view showing a seventh step in the semiconductor device manufacturing method according to the third embodiment.

### DETAILED DESCRIPTION

Embodiments of the present invention will be described below with reference to the accompanying drawings.

### First Embodiment

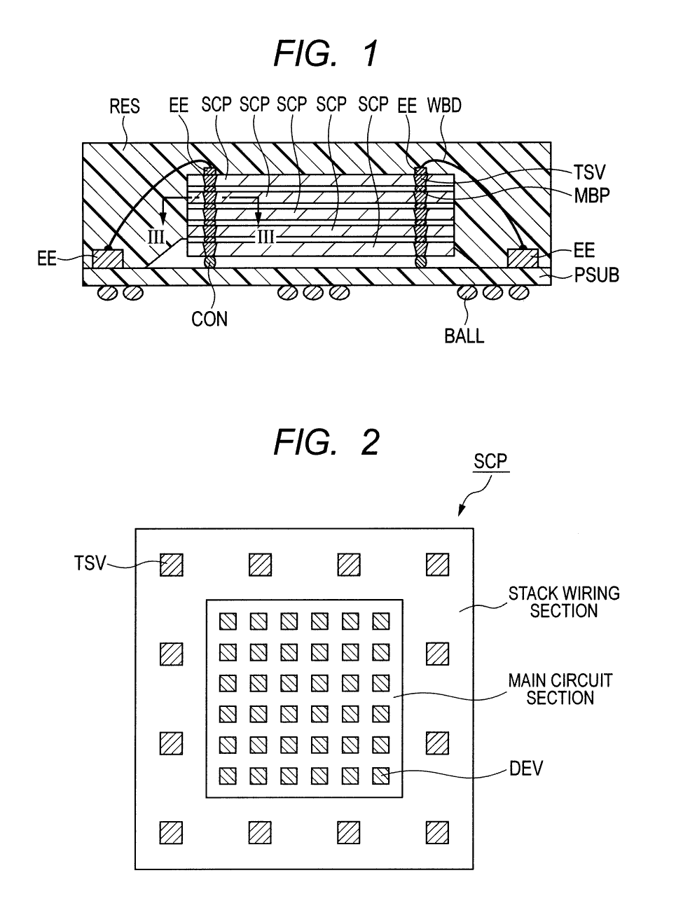

Referring to FIG. 1, a semiconductor device according to a first embodiment of the present invention is an IC package including a package substrate PSUB, a plurality of semiconductor chips SCP, and resin material RES. A multi-layer structure comprised of plural stacked semiconductor chips is disposed on one main surface of the package substrate PSUB. The semiconductor chips SCP disposed on the package substrate PSUB are covered with the resin material RES.

The package substrate PSUB is a substrate serving as a base of the IC package. The semiconductor chips are each a substrate with built-in circuits which constitute, for example, semiconductor memories. The resin material RES plays the role of protecting the semiconductor chips SCP and the package substrate PSUB from external foreign matters, etc.

The semiconductor chips SCP and the package substrate PSUB are formed, for example, by a single crystal of silicon. The semiconductor chips SCP and the package substrate PSUB are coupled together electrically by wire bonding WBD or through connections CON. The wire bonding WBD couples terminal portions EE of the semiconductor chips SCP and terminal portions EE of the package substrate PSUB with each other electrically. Solder balls BALL are formed on a lower surface of the package substrate PSUB. The solder balls BALL are electrical connections for mounting the IC package onto a main surface of for example a printed circuit board.

Referring to FIG. 2, each semiconductor chip SCP has a main circuit section and a stack wiring section. The stack wiring section is disposed on a main surface of the semiconductor chip SCP so as to surround the main circuit section. In the main circuit section are formed a large number of integrated circuits DEV. The integrated circuits DEV are primary circuit portions for driving the semiconductor chip SCP.

In the stack wiring section are formed a plurality of conductive vias TSV (conductive layers) spacedly from one another. The conductive vias each include a through hole extending through the semiconductor chip SCP, the interior of the through hole being filled with a conductor. It is preferable that a metallic material such as, for example, copper, tungsten, aluminum, nickel, gold, silver, tin, or lead, be used as the conductor. Plural semiconductor chips SCP and the conductive vias SV are coupled together mechanically and electrically by microbumps MBP. The microbumps MBP are each a metal member for coupling disposed at a position where a conductive via TSV and the main surface of a semiconductor chip SCP overlap each other when seen in plan.

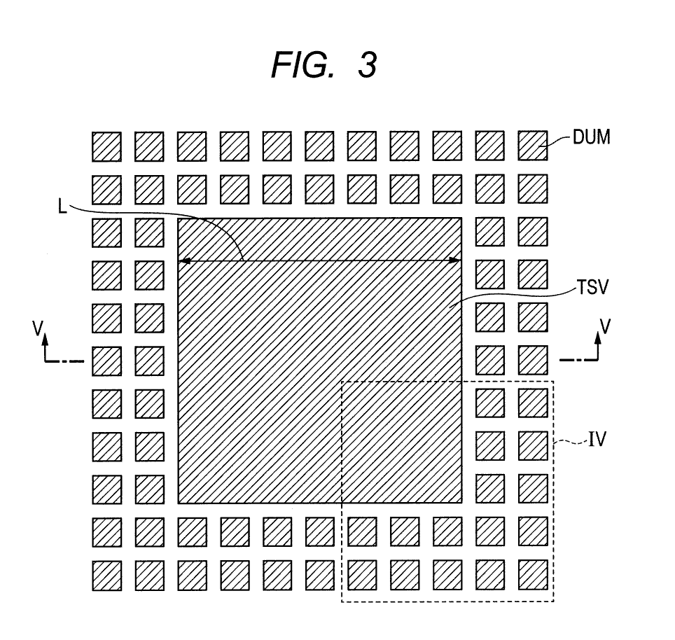

Referring to FIG. 3, each conductive via TSV has a square plane shape with a one side length L for example. On the surface to which an end portion of each conductive via TSV (an end portion in the extending direction of the conductive via TSV, near the surface of the semiconductor chip SCP) is exposed in plan, dummy vias DUM are arranged around the conductive via TSV.

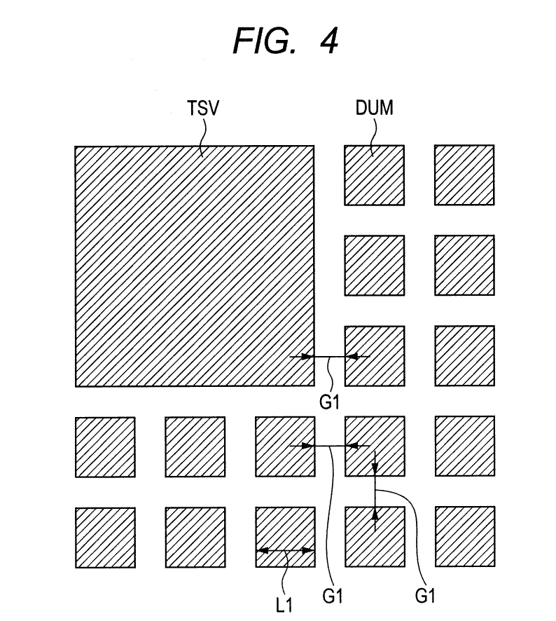

Referring to FIG. 4, each dummy via DUM has a square plane shape with a one side length L1 for example. The distance between adjacent dummy vias DUM and the distance between the conductive via TSV and a dummy via DUM adjacent thereto are G1.

Preferably, the length L1 is one tenth or less of the length L, and the length G1 is one half or more of the length L1.

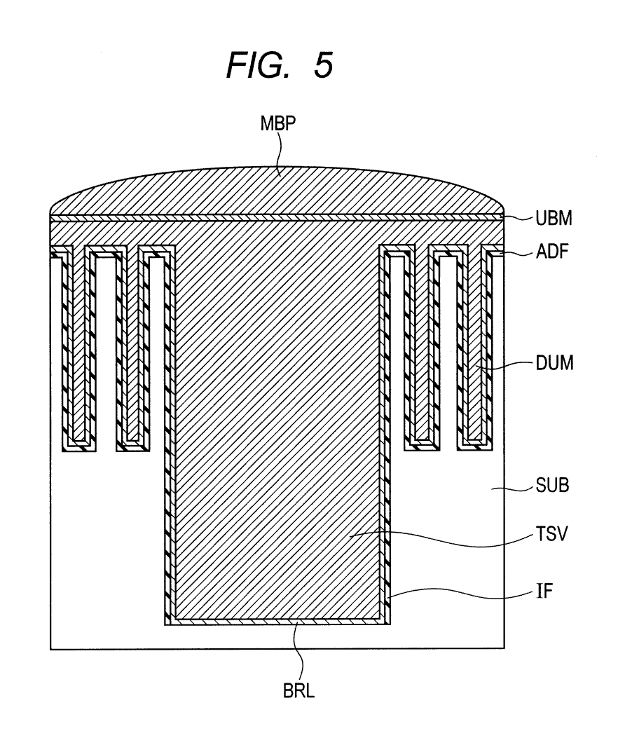

Referring to FIG. 5, the interior of each conductive via TSV and the interiors of the dummy vias DUM are filled with the same conductor CU (conductive material). The conductor CU which fills the interior of the conductive via TSV and the interiors of the dummy vias DUM is disposed so as to make the conductive via TSV and the dummy vias DUM continuous with each other over the conductive via TSV. That is, the interior of the conductive via TSV and the interiors of the dummy vias DUM are coupled together electrically.

Insulating film IF and barrier metal BRL are formed on inner wall surfaces (side wall surfaces and bottom wall surfaces) of the conductive vias TSV and dummy vias DUM formed in the interior of a substrate SUB which constitutes each semiconductor chip SCP, provided only the barrier metal BRL is formed on the bottom wall surface of each conductive vias TSV. This is because in FIG. 5 the bottom wall surface of the conductive via TSV is disposed in the interior of the substrate SUB for the sake of explanation, but actually the bottom wall surface of the conductive via TSV is coupled with another wiring electrically.

Also on the surface coupling the conductive via TSV and the dummy vias DUM, the insulating film IF and the barrier metal BRL are formed so as to make the conductive via TSV and the dummy vias DUM continuous with each other, (like the conductor CU). The insulating film IF and the barrier metal BRL thus formed outside the conductive via TSV and the dummy vias DUM are anti-diffusion films ADF for preventing diffusion of the conductor CU to the interior of the substrate SUB, etc.

The conductor CU and the barrier metal BRL are formed so as to be in a comb shape in a sectional view.

The substrate SUB in question is coupled with another semiconductor chip SCP electrically by microbumps MBP. Preferably, the microbumps MBP are formed on a metal layer designated underbump metal UBM. Preferably, the microbumps MBP are each disposed so as to cover the whole surfaces of the associated conductive via TSV and dummy vias DUM when seen in plan.

In the case where the conductive vias TSV and the dummy vias DUM have a square plane shape, it is preferable that the dummy vias DUM be disposed so as to assume a point symmetry position with respect to a central part (center) of the associated conductive via TSV. That is, the dummy vias DUM are arranged in point symmetry centered at the central part of an end portion of the conductive via TSV when seen in plan.

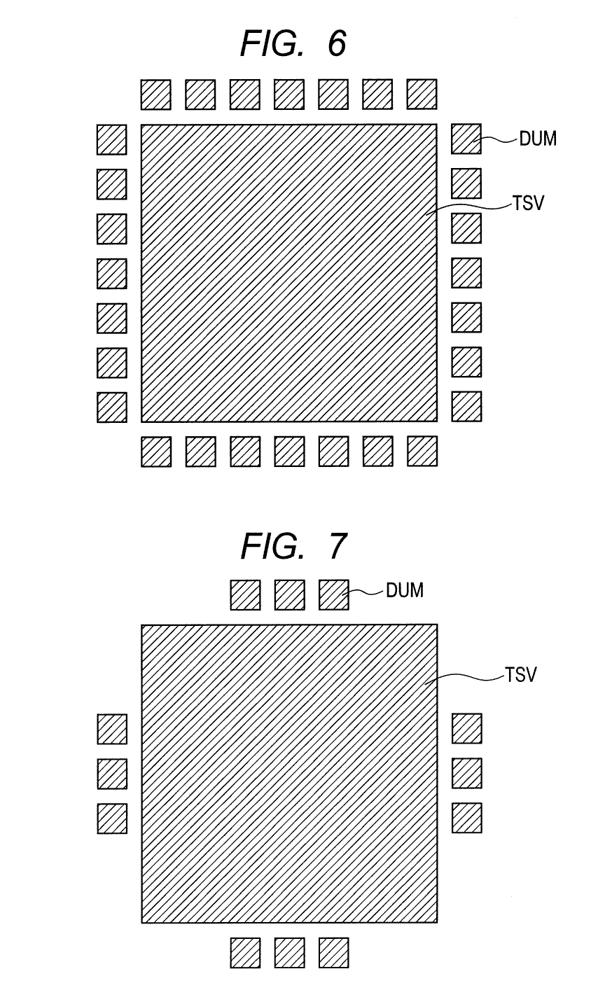

For positioning the dummy vias DUM in point symmetry with respect to the center of the conductive via TSV, the dummy vias DUM may be arranged for example along each side of the conductive via TSV as shown in FIG. 6 or may be arranged near only part (only near the mid-portion) of each side of the conductive via TSV. Or, as shown in FIG. 8, a dummy via DUM may be disposed only near an end of each side of the conductive via TSV. The number of dummy via DUM disposed along each side of the conductive via TSV may be an arbitrary number selected from 1, 2, or more.

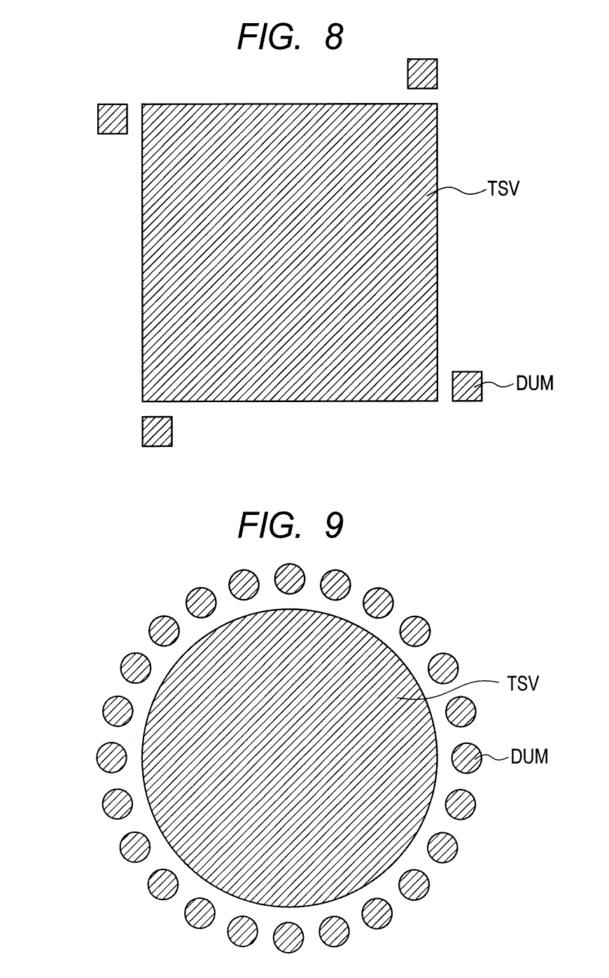

Also in the case where dummy vias DUM are formed as in FIGS. 6 to 8, it is preferable that the length L (see FIG. 4) of one side of the square of each dummy via DUM be one tenth or less of the length L (see FIG. 3) of one side of the square of the conductive via TSV. It is preferable that the distance G1 (see FIG. 4) between adjacent dummy vias DUM be L1/2 or more.

However, the planar shape which the conductive via TSV and the dummy vias DUM can take is not limited to the square. For example, it may be a planar shape having point symmetry with respect to the center such as, for example, a circle, an angular shape of a positive even number (e.g., regular hexagon or regular octagon), or a parallelogram. Referring to FIG. 9, for example in the case where the conductive via TSV and the dummy vias DUM have a circular plane shape, it is preferable that the dummy vias DUM be arranged in an area of a certain distance from the center of the conductive via TSV and at equal intervals in the circumferential direction. Also in this case, the dummy vias DUM are arranged so as to be positioned at point symmetry with respect to the center of the conductive via TSV.

In the case of FIG. 9 it is preferable that the diameter R1 of each dummy via DUM be one tenth or less of the diameter R of the conductive via TSV and that the distance between adjacent dummy vias DUM and the distance between the conductive via TSV and each dummy via DUM be R1/2 or more.

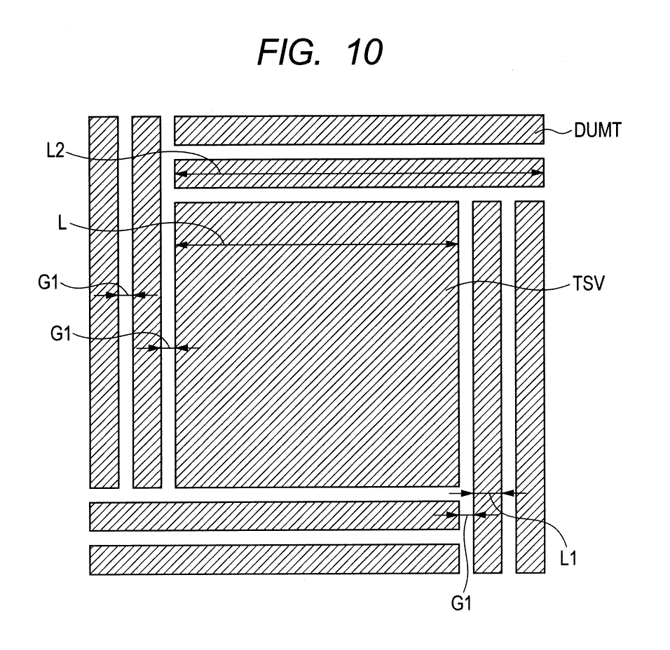

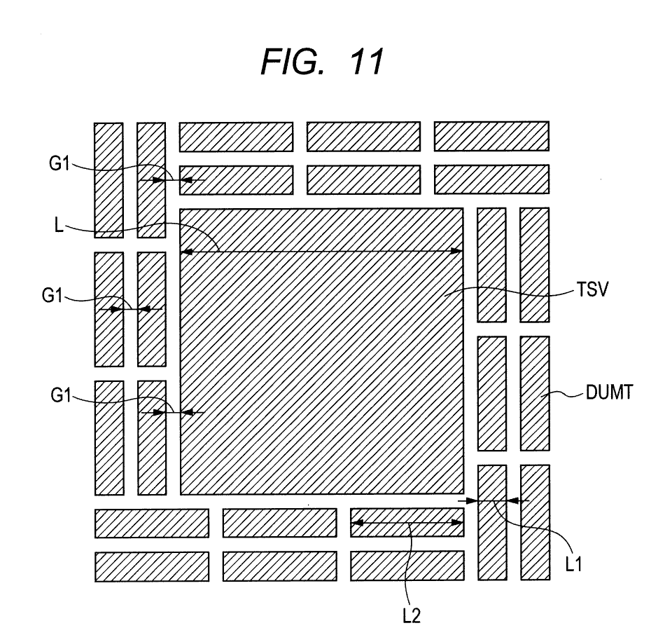

Referring to FIGS. 10 and 11, there may be adopted a configuration such that dummy trenches DUMT are formed around the conductive via TSV. The shape of each dummy trench DUMT has a recess similar to that of each dummy via DUM in section, but the dummy trenches DUMT are different from the dummy vias DUM in that their planar shape is rectangular.

It is preferable that a short-side length L1 of the rectangle of each dummy trench DUMT be one tenth or less of a one-side length L of the conductive via TSV. A long-side length L2 of each dummy trench DUMT may be larger than the length L of the conductive via TSV for example as shown in FIG. 10 or may be smaller than the length L of the conductive via TSV for example as shown in FIG. 11. Preferably, each dummy trench DUMT is disposed so that long sides thereof are parallel to a side of the conductive via TSV. However, unlike the dummy vias DUM, the dummy trenches DUMT need not be positioned at point symmetry with respect to the center of the conductive via TSV. Preferably, the distance G1 between adjacent dummy trenches DUMT is L1/2 or more.

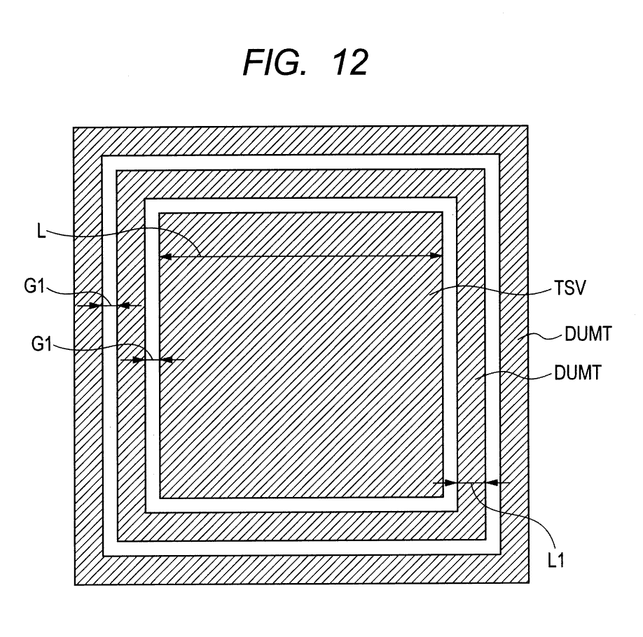

Referring to FIG. 12, it is more preferable that the dummy trenches DUMT be each formed in the shape of a quadrangular ring around the conductive via TSV. That is, it is preferable that the dummy trenches DUMT be each disposed so as to be continuous in the direction along the outer periphery of the conductive via TSV.

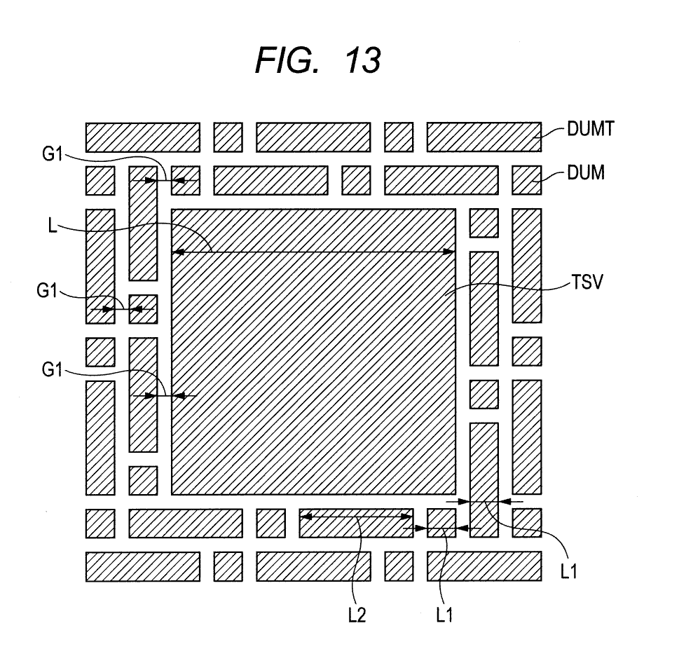

Referring further to FIG. 13, both dummy vias DUM and dummy trenches DUMT may be formed mixedly around the conductive via TSV. Also in the examples of FIGS. 12 and 13 it is preferable that such conditions as L1 and G1 be made the same as in the other examples.

Preferably, the dummy vias DUM and the dummy trenches DUMT both described above are disposed so that a bottom wall surface of each of them is positioned in the interior of the substrate SUB (see FIG. 5) without the depth thereof reaching the other main surface from one main surface of the substrate. By so doing, conductive patterns, etc. to be disposed near the conductive via TSV are formed smoothly without being obstructed by dummy vias DUM, etc.

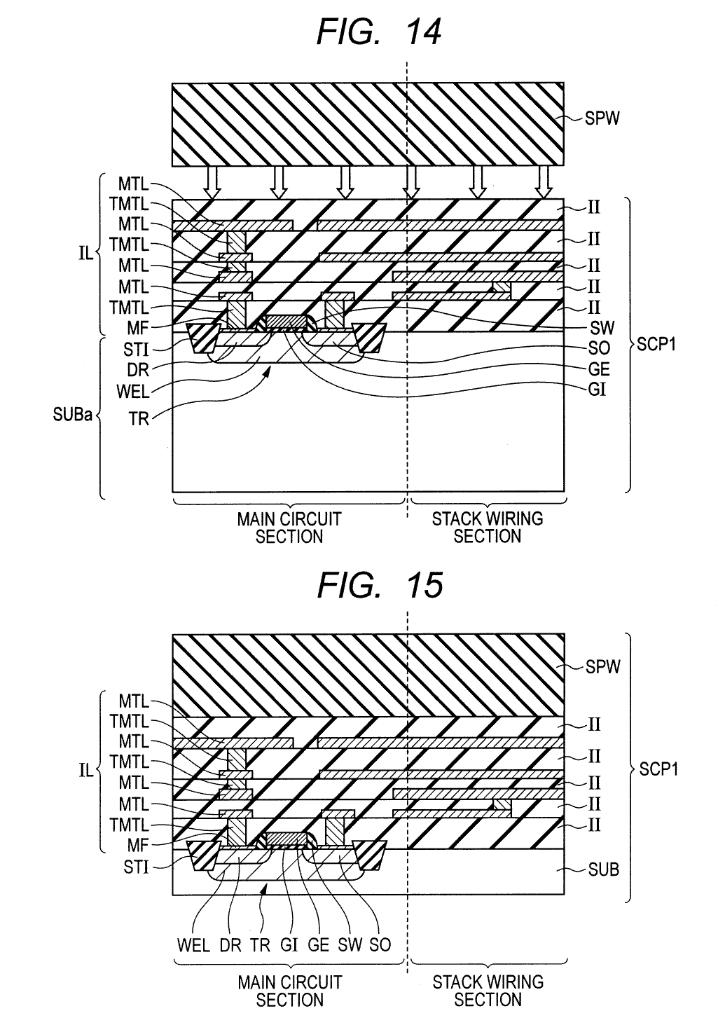

Next, a description will be given below about a method for fabricating a stacked structure of the semiconductor device, especially plural semiconductor chips SCP, according to this embodiment, while making reference to FIGS. 14 to 21.

Referring to FIG. 14, a substrate SUBa having main surfaces is provided. For example, the substrate SUBa is formed by a single crystal of a semiconductor material such as silicon. A well region WEL of a conductivity different from that of the substrate SUBa is formed on one main surface (first main surface, upper main surface) of the substrate SUBa and a transistor TR (a first semiconductor element) is formed in the interior of the well region WEL and on the first main surface of the substrate SUBa.

The transistor TR is formed plurally in the interior (on the main surface) of the substrate SUB, especially in an active region surrounded with a separation insulator ST1. For example, a MIS transistor (Metal Insulator Semiconductor) is formed as each transistor TR. The MIS transistor has a source region SO, a gate electrode GE, a gate insulator GI, a drain region DR, and a side wall insulator SW. A metal film MF is formed on each of the source region SO and the drain region DR.

A plurality of interlayer dielectric films II are formed over the transistor TR and a metal wiring (first wiring) is formed on a main surface of each interlayer dielectric film II. Further, a metal conductive film TMTL for coupling metal wirings MTL with each other is formed. The metal film MF is formed for diminishing contact resistance at the time of coupling the source region and the drain region with metal wirings MTL electrically. These are all formed of known materials by related methods.

The stacked metal wirings MTL and metal conductive films TMTL constitute a wiring layer IL. Electric signals generated from the transistors TR are transmitted through the wiring layer IL. Thus, in FIG. 14, the semiconductor chip SCP1 has a multi-layer interconnection structure. However, the mode of the semiconductor chip SCP1 is not always limited thereto.

The area where the substrate SUBa and the wiring layer IL are stacked becomes the semiconductor chip SCP1 (first semiconductor substrate) and the transistors TR are formed in a main circuit section of the semiconductor chip SCP1.

A supporting substrate SPW is affixed to an upper surface of an interlayer dielectric film II. The supporting substrate SPW is provided for preventing the surface of the semiconductor chip SCP1 from being damaged in the next step. Preferably, the supporting substrate SPW is a substrate formed of, for example, glass (silicon oxide), silicon, gallium arsenide, or silicon carbide. The supporting substrate SPW is affixed to the film surface by any known method using, for example, a double-coated tape.

Referring to FIG. 15, the substrate SUBa is subjected to a processing to reduce its thickness. More specifically, by a known method such as, for example, a chemical mechanical polishing method called CMP (Chemical Mechanical Polishing), the substrate SUBa is polished, starting with the main surface on the side opposite to the main surface on which the transistors TR are formed. It is preferable that the thus-polished surface of the substrate SUB become a flat surface.

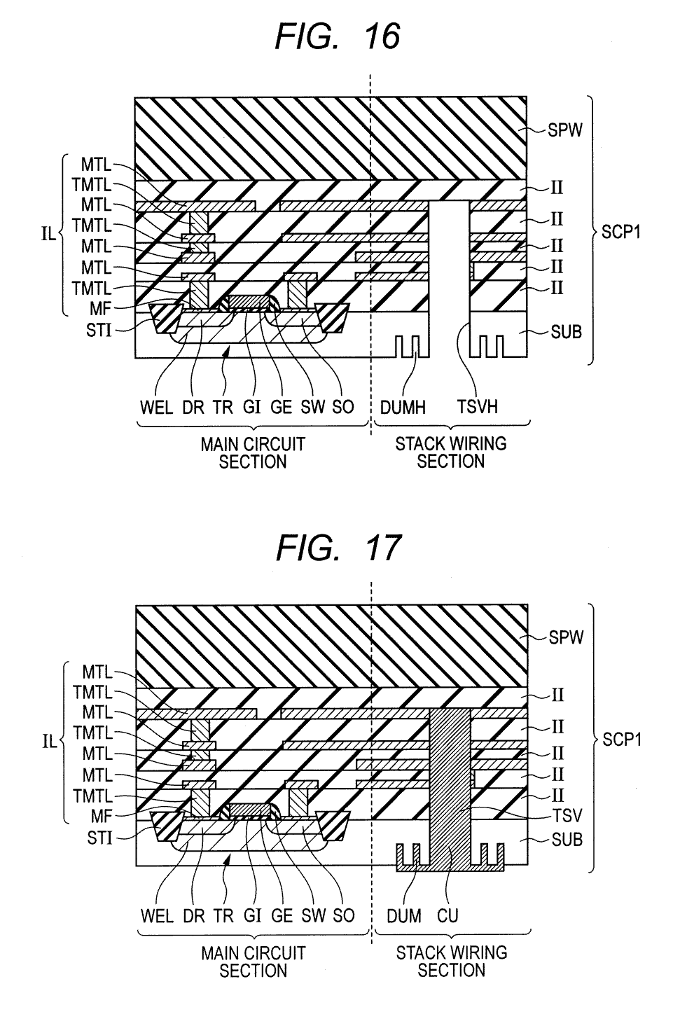

Referring to FIG. 16, by the known technique for photomechanical process and etching technique, conductive via holes TSVH (through holes) and dummy via holes DUMH (recesses) are formed in the stack wiring section (see FIG. 2) of the semiconductor chip SCP1. The conductive via holes TSVH and dummy via holes DUMH are slots (holes) for forming the conductive vias TSS and dummy vias DUM (dummy trenches DUMT) respectively.

It is preferable that the conductive via holes TSVH be formed so as to extend through a first main surface and a second main surface (a lower main surface) confronting each other of the substrate SUB, further through the interlayer dielectric films II, and reach the top surface of the wiring layer IL. It is preferable that the conductive via holes TSVH and dummy holes DUMH be formed so as to have such planar shapes and layouts as shown in FIGS. 3 and 6. Dummy via holes DUMH are formed around an end portion of each conductive via hole TSVH so as to be exposed to the second main surface of the substrate SUB side by side with the end portion of the conductive via hole TSVH.

Preferably, the dummy via holes DUMH are each formed at a depth such that its bottom wall surface is present in the interior of the substrate SUB.

Referring to FIG. 17, a conductor CU, e.g., copper, is filled in the interior of each conductive via hole TSVH and that of each dummy via hole DUMH. Through this process, the conductive via hole TSVH becomes a conductive via TSV (conductive layer) and the dummy via hole DUMH becomes a dummy via DUM or a dummy trench DUMT. In the following description it is assumed that a dummy via DUM is formed.

It is preferable that the filling and the formation of film of the conductor CU be done all at a time for example by combining electrolytic plating with the technique for photomechanical process or etching technique.

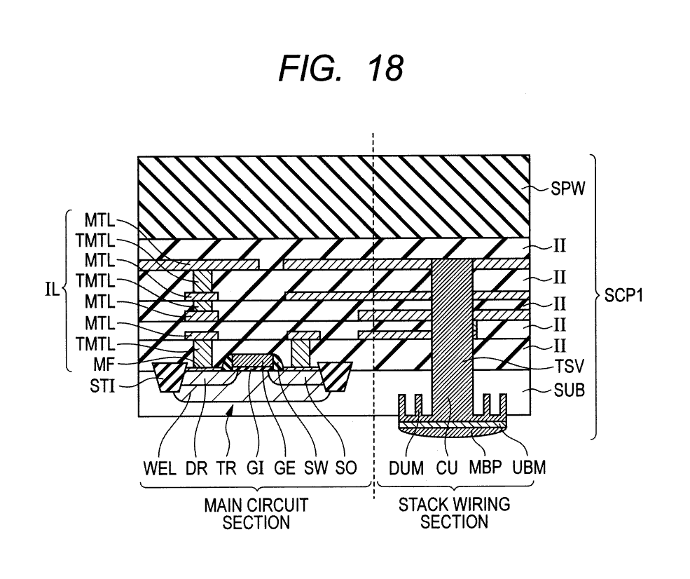

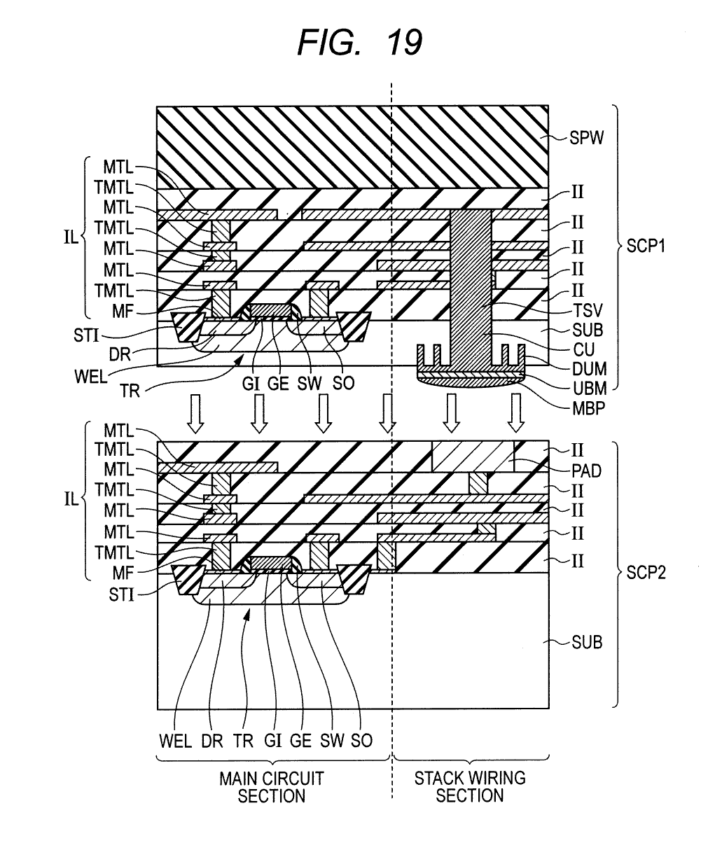

Referring to FIG. 18, underbump metal UBM and microbump MBP are formed in this order on the main surface where each conductive via TSV and the associated dummy vias DUM are formed. The underbump metal UBM and the microbump MBP are formed for example by a combination of CVD, vacuum deposition, or sputtering, with the technique for photomechanical process and etching technique.

The underbump metal UBM and the microbump MBP are each formed of a known material. For example, it is preferable that the underbump metal UBM be formed of nickel, gold, copper, aluminum, silicon, or an alloy thereof, and that the microbump MBP be formed of tin, silver, copper, lead, or an alloy thereof. It is preferable that the underbump metal UBM and the microbump MBP be formed on the main surface of the substrate SUB so as to cover all of each conductive via TSV, dummy vias DUM, and conductor CU formed as film near those vias.

Referring to FIG. 19, a separately provided semiconductor chip SCP2 (a second semiconductor substrate) formed with transistors TR (second semiconductor elements) and the conductive vias TSV of the semiconductor chip SCP1 are coupled together electrically by a related known method such as, for example, heat treatment of microbumps MBP. At this time, the two semiconductor chips SCP1 and SCP2 are stacked. More specifically, for example, pad electrodes PAD (wirings) each formed on a metal wiring MTL (second wiring) or on a metal conductive film TMTL of the semiconductor chip SCP2 and the conductive vias TSV of the semiconductor chip SCP1 are coupled together electrically by microbumps MBP.

In FIG. 19, the semiconductor chip SCP2 has the same multilayer interconnection structure as the semiconductor chip SCP1. However, the mode of the semiconductor chip SCP2 is not always limited thereto.

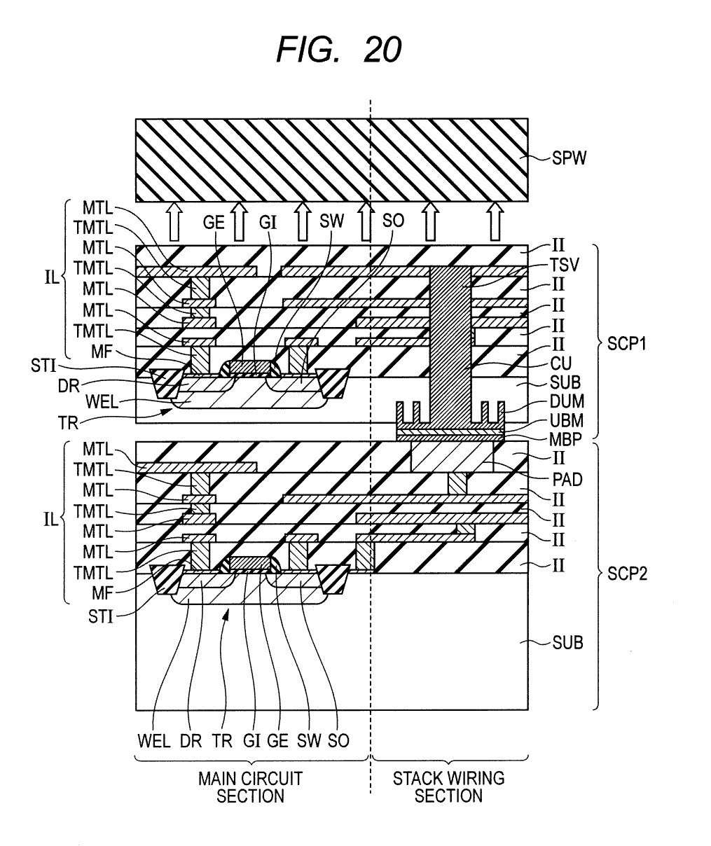

Referring to FIG. 20, the supporting substrate SPW is separated from the semiconductor chip SCP1.

After stacking of the semiconductor chips SCP1 and SCP2, the portion around each microbump MBP is a vacant space. However, the vacant space may be filled with for example the same insulating film as the interlayer dielectric film II.

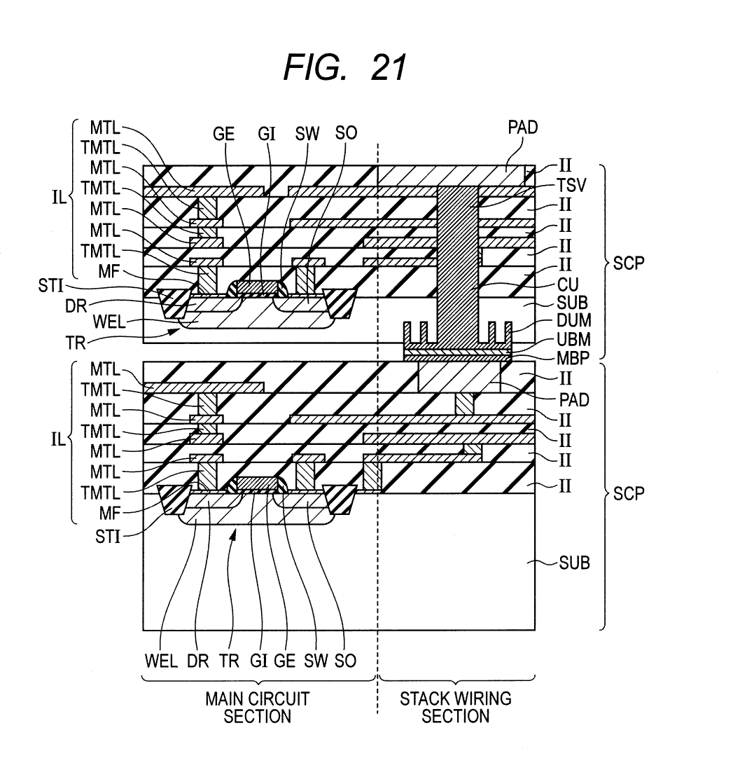

Referring to FIG. 21, a pad PAD is formed over each conductive via TSV of the semiconductor chip SCP1. The pad PAD is formed of a known metallic material, e.g., aluminum, by the known technique for photomechanical process and etching technique. An electric signal can be inputted from each pad PAD in the semiconductor chip SCP1 and be transmitted to the semiconductor chip SCP2 through the associated conductive via TSV and microbump MBP.

In this way there is formed a stacked structure wherein the semiconductor chips SCP1 and SCP2 are coupled together electrically. For example, such an IC package as shown in FIG. 1 is formed by further stacking semiconductor chips SCP (see FIG. 1) on the stacked structure described above.

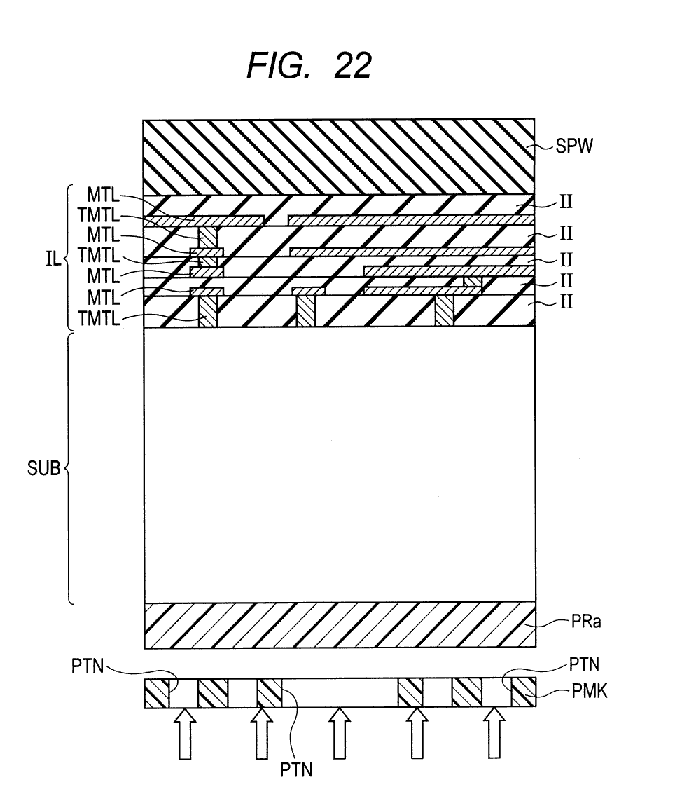

The steps of forming the conductive vias TSV and dummy vias DUM, which are shown in FIGS. 16 to 18, will be described below in more detail with reference to FIGS. 22 to 30. In FIGS. 22 to 30 there is illustrated only the stack wiring section shown in FIGS. 14 to 21.

Referring to FIG. 22, photoresist PRa is applied onto one main surface (second main surface) of the substrate SUB. A photomask PMK formed with desired patterns PTN is set onto the photoresist PRa and is subjected to exposure by the known exposure technique.

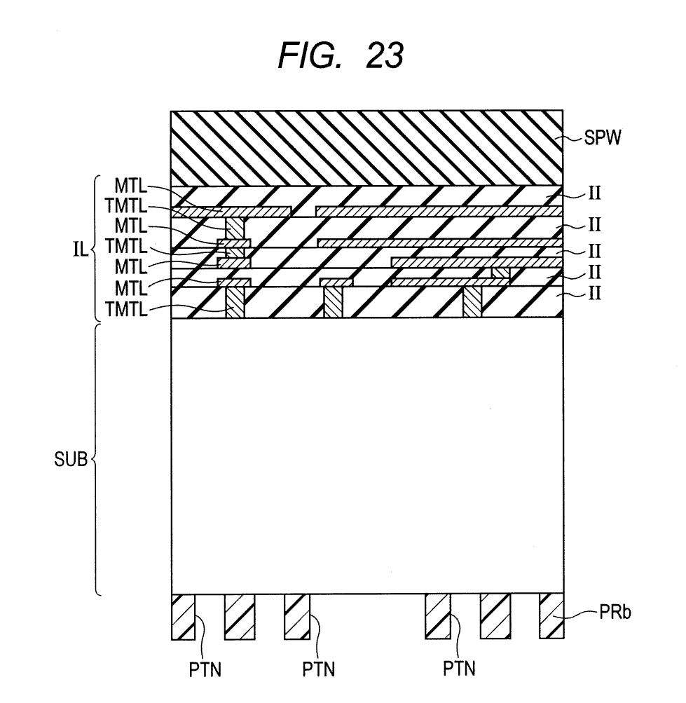

Referring to FIG. 23, the photoresist PRa having been subjected to exposure is then subjected to development. As a result, in conformity with the shape of the patterns formed in the photomask PMK, the photoresist PRa is removed partially, leaving photoresist PRb. The patterns PTN are apertures resulting from the partial removal of the photoresist PRb.

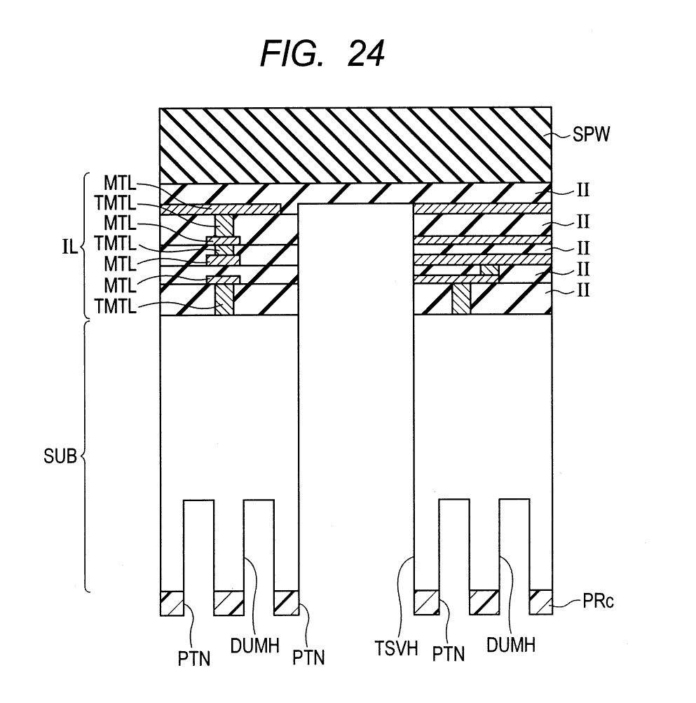

Referring to FIG. 24, with the photoresist PRb as a hard mask, the known photomechanical process (exposure, development) and etching are performed. As a result, the substrate SUB and the interlayer dielectric films II are etched in conformity with the patterns PTN formed in the photoresist PRb and conductive via holes TSVH and dummy via holes DUMH are formed simultaneously starting from the second main surface.

The etching is performed so that the conductive via holes TSVH are formed deeper than the dummy holes DUMH, more specifically, each conductive via hole TSVH extends as a through hole from the second main surface up to the first main surface, and the etching be performed up to a still upper side than the first main surface. Conversely speaking, it is preferable that the dummy via holes DUMH be formed shallower than the conductive via holes TSVH and that the bottom wall surface of each dummy via hole DUMH be formed in the interior of the substrate SUB. The reason why there occurs such a difference in depth between both vias is because both are different in respective areas when seen in plan. That is, each conductive via hole TSVH, which is the larger in area when seen in plan, requires a longer etching time than each dummy via hole DUMH and is therefore formed deeper.

The conductive via holes TSVH are formed so as to extend through the first and second main surfaces of the substrate SUB and reach the metal wirings MTL in the wiring layer IL. On the other hand, the dummy via holes DUMH are formed around second main surface-side end portions of the conductive via holes TSVH. The conductive via holes TSVH and the dummy via holes DUMH are formed so as to be exposed to the second main surface of the substrate SUB. The photoresist PRb is etched simultaneously with etching of the substrate SUB, etc. and is thus thinned into photoresist PRc.

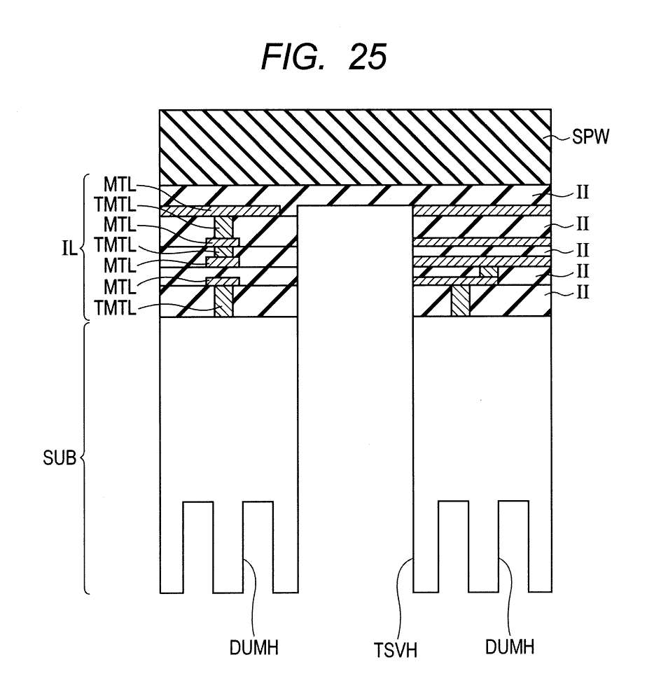

Referring to FIG. 25, the photoresist PRc is removed by the known asking process and wet etching technique.

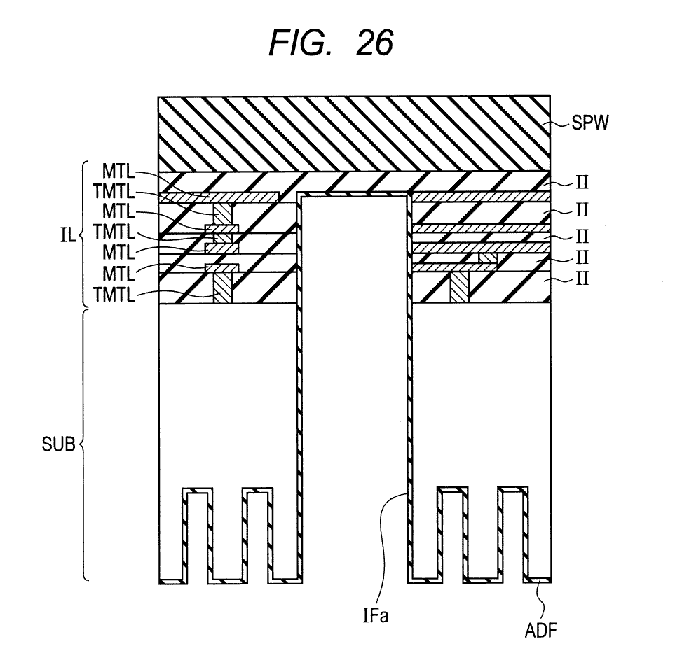

Referring to FIG. 26, an insulating film IFa, e.g., silicon oxide film, is formed for example by CVD on the second main surface of the substrate SUB and on an inner wall surface of each conductive via hole TSVH and on inner wall surfaces of the dummy via holes DUMH.

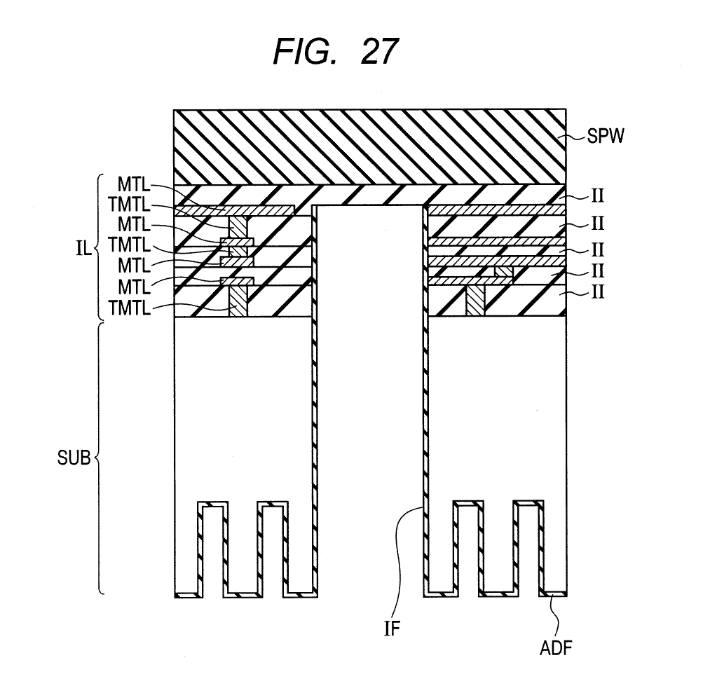

Referring to FIG. 27, the insulating film IFa formed on the bottom wall surface of each conductive via hole TSVH is removed, forming an insulating film IF, by the known technique for photomechanical process and etching technique.

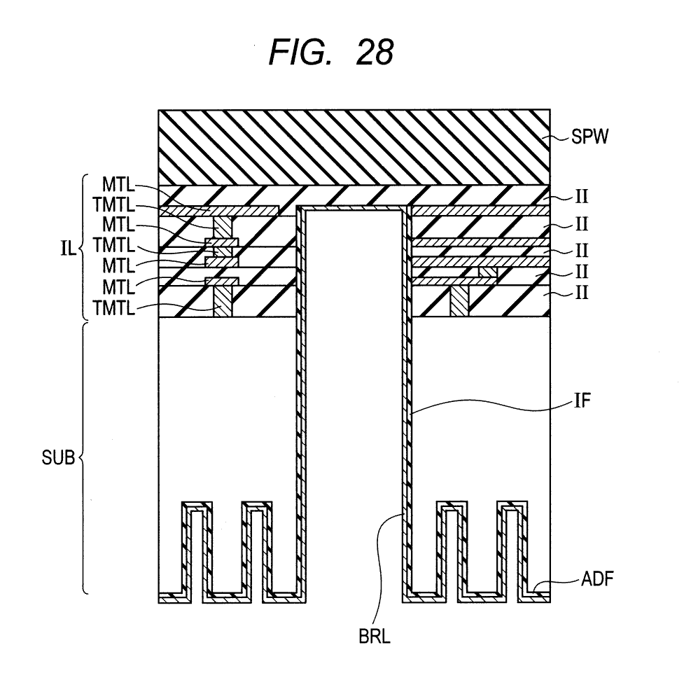

Referring to FIG. 28, barrier metal BRL is formed on the insulating film IF and also on the bottom wall surface of each conductive via hole TSVH by a known film forming method such as CVD or vacuum deposition. Preferably, the barrier metal BRL is a thin film of a nitride or oxide of, for example, tantalum, tungsten, titanium ruthenium, nickel, molybdenum, or silicon, or a nitride or oxide of an alloy containing, for example, tantalum, tungsten, titanium, ruthenium, nickel, or molybdenum.

Further, a seed metal (not shown) as a plating electrode film is formed on the second main surface (on the barrier metal BRL) of the substrate SUB. Preferably, the seed metal is a thin film of, for example, copper, silver, gold, aluminum, nickel, titanium, or an alloy thereof.

In FIGS. 17 to 21 referred to previously, the insulating film IF and the anti-diffusion film ADF are not shown to make the drawings easier to see.

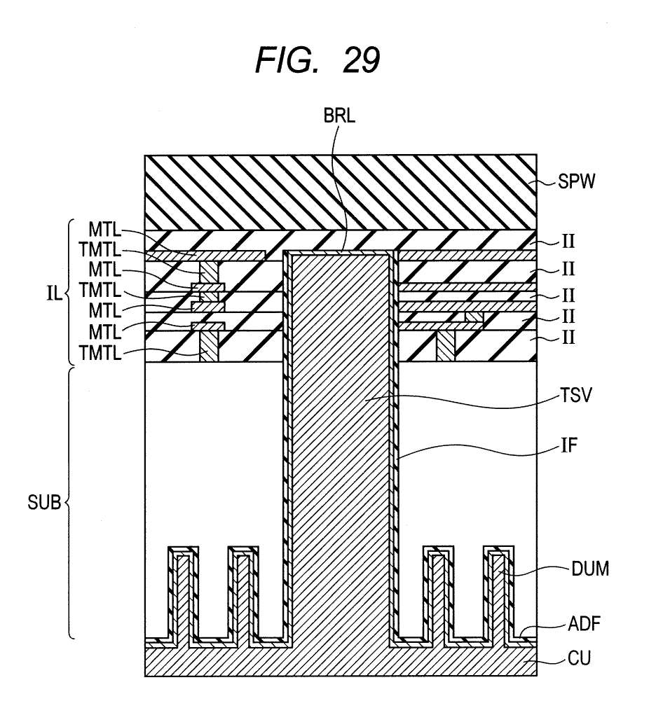

Referring to FIG. 29, the interiors of the conductive via holes TSVH and the dummy via holes DUMH are each filled with a conductor CU, e.g., copper.

It is preferable that a film of the conductor CU be formed simultaneously also in the vicinity of the conductive vias TSV and dummy vias DUM when seen in plan. That is, it is preferable that the conductor CU fill the interiors of the conductive via holes TSVH and dummy via holes DUMH and cover the whole surfaces of the exposed ends and the environs (vicinities) thereof of the conductive vias TSV and dummy vias DUM. Thus, it is preferable that a continuous and integral conductor CU be formed at a time in the interiors of the conductive via holes TSVH and dummy via holes DUMH and also near the conductive vias TSV and dummy vias DUM formed on the second main surface. It is preferable that the conductor CU be formed, for example, by an electrolytic plating method.

Thereafter, a photomask is put on the conductor CU and both conductor CU and anti-diffusion film ADF are subjected to wet etching so that the area of the conductor CU in each conductive via and the associated dummy vias when seen in plan becomes almost equal to the area of underbump metal UBM and that of microbump MBP. That is, the conductor CU and the anti-diffusion film ADF are patterned so that the conductor CU on the second main surface remains in a substantially overlapping area with underbump metal UBM and microbump MBP when seen in plan.

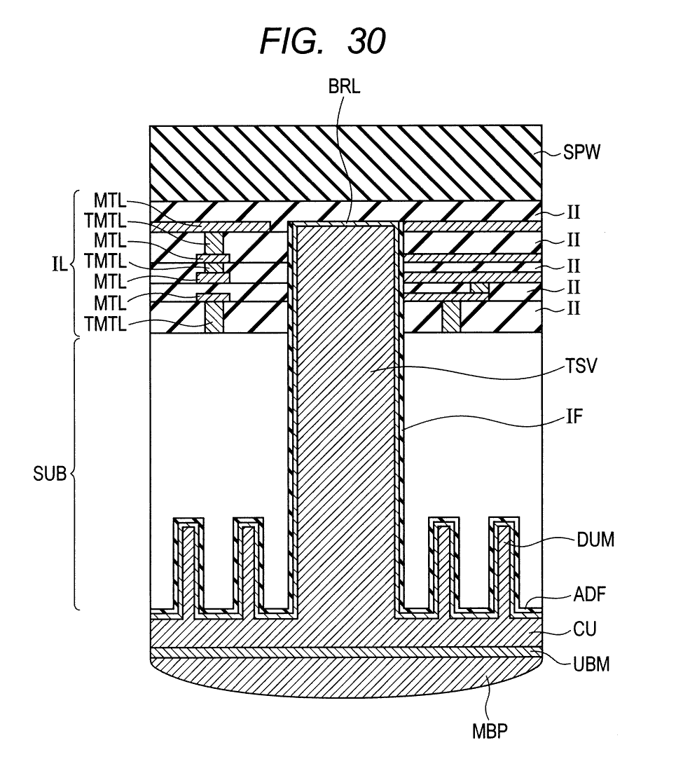

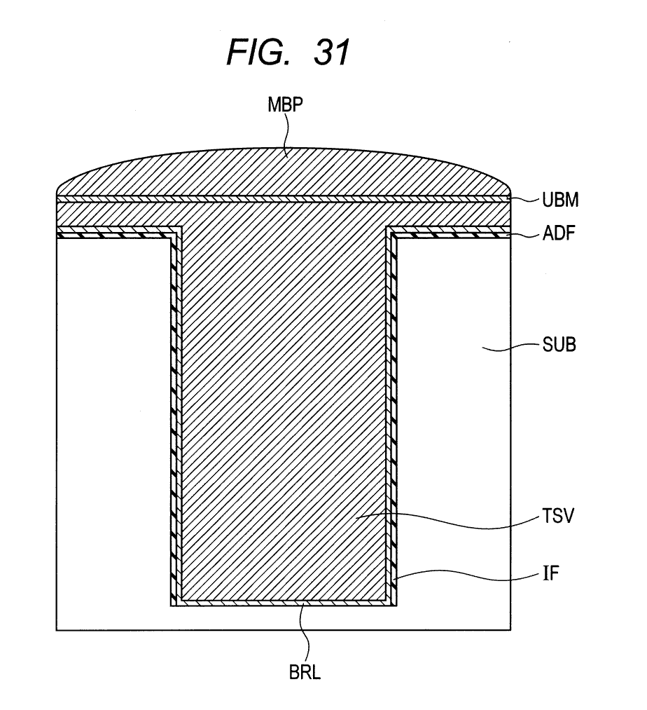

Referring to FIG. 30, underbump metal UBM and microbump MBP are formed by the known film forming technique, technique for photomechanical process, and etching technique. At this time it is preferable that the underbump metal UBM and the microbump MBP be formed so as to cover the whole surface of an end portion of each conductive via TSV and dummy vias DUM. Therefore, it is preferable that for example the area near the conductive via TSV and dummy vias DUM be also covered with the underbump metal UBM and microbump MBP. Thus, it is preferable that continuous and integral underbump metal UBM and microbump MBP be formed simultaneously not only on an end portion of each conductive via TSV and dummy vias DUM but also on the area near the conductive via TSV and dummy vias DUM.

In accordance with the above procedure there is formed the semiconductor chip SCP1 of the configuration shown in FIG. 18. Next, a description will be given below about the function and effect of this embodiment.

Once dummy via holes DUMH are formed around each conductive via hole TSVH, the conductor CU is filled more positively in the interior of the conductive via hole TSVH. That is, the conductor CU of higher quality can be filled in the interior of each conductive via hole TSVH in higher efficiency.

Since the conductive via hole TSVH is large in depth relative to its width, it has a shape of a large aspect ratio. Therefore, for example by electrolytic plating, it is difficult to fill the conductor CU in high quality in the interior of the conductive via hole TSVH. That is, an inconvenience is likely to occur such that the conductor CU is filled non-uniformly in the interior of each conductive via TSV or the percentage fill of the conductor CU becomes low in a deep region. There is the possibility that the occurrence of such an inconvenience may affect the conductivity and electrical characteristics of the conductive via TSV.

In this connection, if recesses called dummy via holes DUMH are formed, a field concentration occurs around each conductive via hole TSVH in electrolytic plating. Therefore, in comparison with the case of forming a conductive via TSV with no dummy via hole DUMH formed therearound, field concentration to the interior of the conductive via hole TSVH becomes easier and hence it becomes easier to bury the conductor CU to the interior of the conductive via hole TSVH. That is, the burying of the conductor CU into the conductive via hole TSVH is done in a more positive manner.

At this time, if the conductor CU is formed as film also around the conductive via hole TSVH and dummy via holes DUMH, it is possible to further enhance the effect of field concentration to the interior of the conductive via hole TSVH. That is, the conductor CU filled in the interior of each conductive via hole TSVH can be made higher in quality and hence it is possible to ensure a good electrical conduction between mutually stacked semiconductor chips in the IC package having the stacked structure.

Besides, if the conductor CU is filled and formed as film at a time in each conductive via hole TSVH and dummy via holes DUMH and around them, the filling and film-forming area of the conductor CU becomes larger. Consequently, the adherence between the conductor CU and the substrate SUB is more improved.

If mutually stacked semiconductor chips CP are coupled together by microbumps MBP, the adherence between the substrates SUB and wirings (pad electrodes PAD) of the semiconductor chips SCP and the microbumps MBP is more improved. Accordingly, the stacked structure of the semiconductor chips SCP can be made higher in quality.

Moreover, the underbump metal UBM and the microbumps MBP are formed on the second main surface of the substrate SUB so as to each cover the whole surface of each conductive via TSV and the associated dummy vias DUM. By so doing, for example in comparison with the case where microbumps, etc. are formed on only the conductive vias TSV, with no dummy via DUM present, the area of contact among the substrate SUB, underbump metal UBM and microbumps MBP becomes larger. Consequently, it is possible to improve the adherence among the substrate SUB, underbump metal UBM, and microbumps MBP.

Further, if each conductive via TSV and dummy vias DUM have a planar shape of point symmetry centered on the central part of the conductive via TSV, then at the time of filling the conductor CU, an electric field is applied uniformly to various regions in the interior of the conductive via TSV and hence electrolytic plating is done more uniformly. Likewise, on the second main surface of the substrate SUB, if dummy vias DUM are arranged in a planar shape of point symmetry centered on the central part of the conductive via TSV, an electric field is applied uniformly to various regions in the interior of the conductive via TSV and hence electrolytic plating is done more uniformly. That is, an electrical conduction by the conductive via TSV can be stabilized.

Further, by adopting the foregoing conditions as to the size of each conductive via TSV and that of each dummy via DUM and the spacing between each conductive via TSV and a dummy via DUM adjacent thereto, the effect of making the electrolytic plating more uniform is further enhanced.

Further, for example like the dummy trenches DUMT shown in FIG. 12, if a recess is formed around each conductive via TSV so as to be continuous along the outer periphery of the conductive via TSV, a stronger electric field can be applied to the interior of the conductive via TSV more positively. Therefore, the conductor CU can be filled in the interior of the conductive via TSV more easily and in a higher percentage fill.

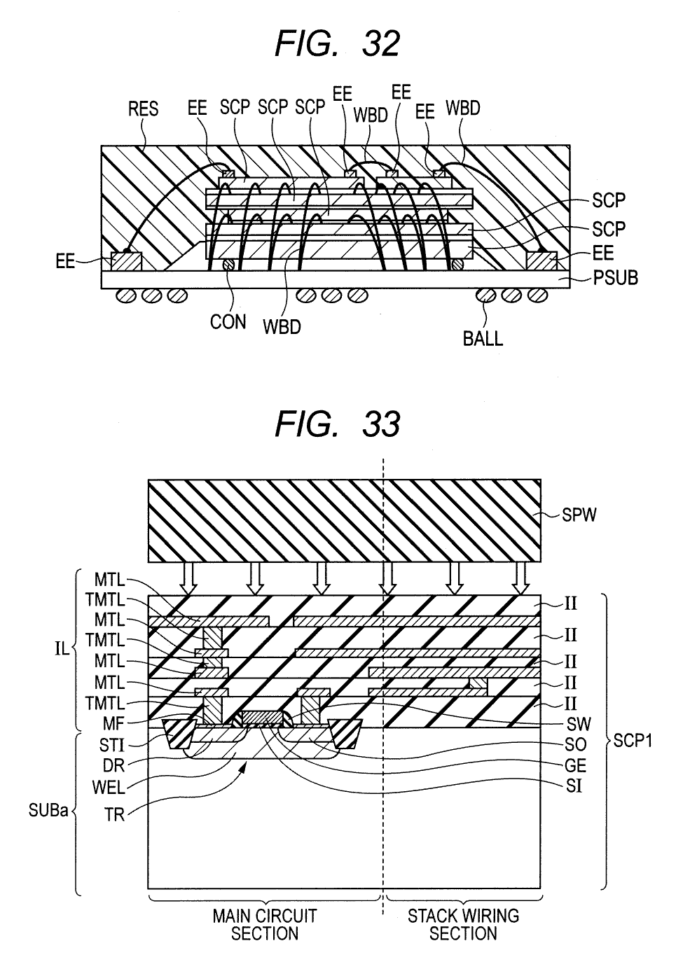

In the IC package wherein stacked semiconductor chips are conducted with each other by the conductive vias TSV according to this embodiment, the delay of electric signals is suppressed and the degree of integration of semiconductor chips is improved, as compared with an IC package having a multi-layer interconnection structure wherein electrical coupling is done by wire bonding WBD as shown, for example, in FIG. 32.

As a modification of specially the step shown in FIG. 29 out of the steps described above, the insulating film IF and barrier metal BRL on the second main surface of the substrate SUB may be partially removed, making the second main surface of the substrate SUB a flat surface, after formation of the conductor CU. In this case, the barrier metal BRL on the second main surface of the substrate SUB becomes thinner.

In this case, moreover, it becomes unnecessary to provide such a photomask on the conductive via TSV and dummy vias DUM for patterning the anti-diffusion film ADF as substantially overlaps the underbump metal UBM and microbump MBP when seen in plan. In this case, the possibility of the barrier metal BRL causing short-circuit and obstructing the transfer of electric signals due to the anti-diffusion film ADF (barrier metal BRL) being disposed throughout the whole of the second main surface without being patterned, is eliminated. This is because the volume of the conductive via TSV is very small in comparison with the volume of the barrier metal BRL (anti-diffusion film ADF) and therefore the influence of leakage current in the barrier metal BRL can be substantially ignored.

It is optional whether the underbump metal UBM and the microbump MBP formed after the above CMP is to be formed so as to cover only the conductive via TSV or cover both conductive via TSV and dummy vias DUM.

### Second Embodiment

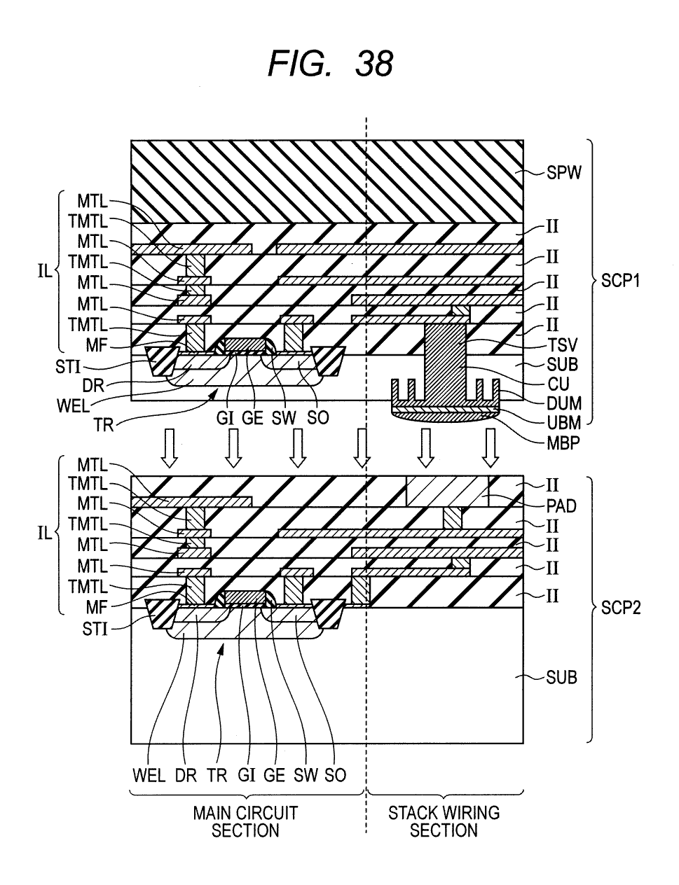

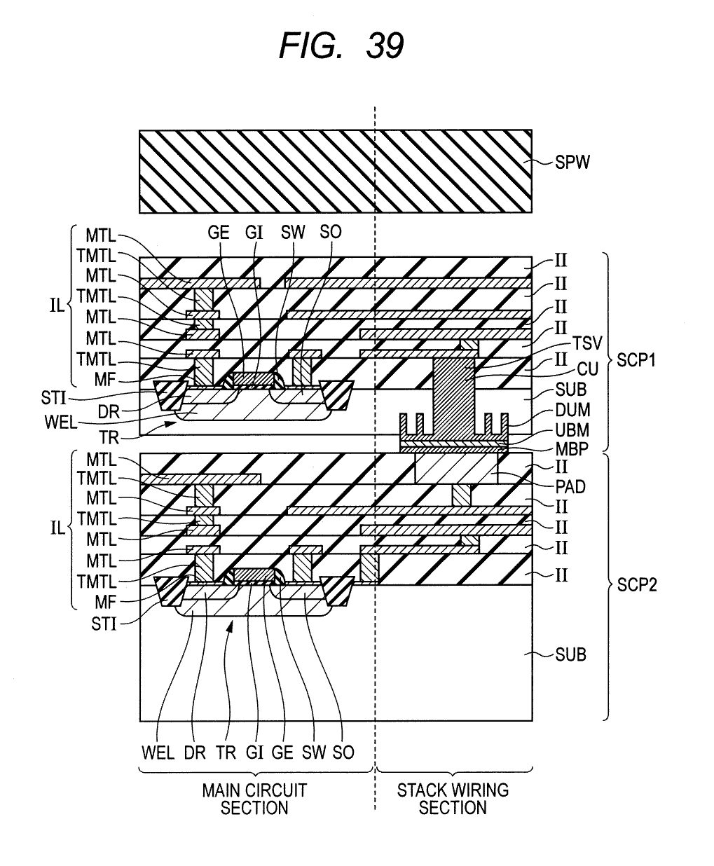

In comparison with the above first embodiment this second embodiment is different in the method for stacking semiconductor chips. A description will be given below about a method for fabricating a stacked structure of plural semiconductor chips SCP with reference to FIGS. 33 to 39.

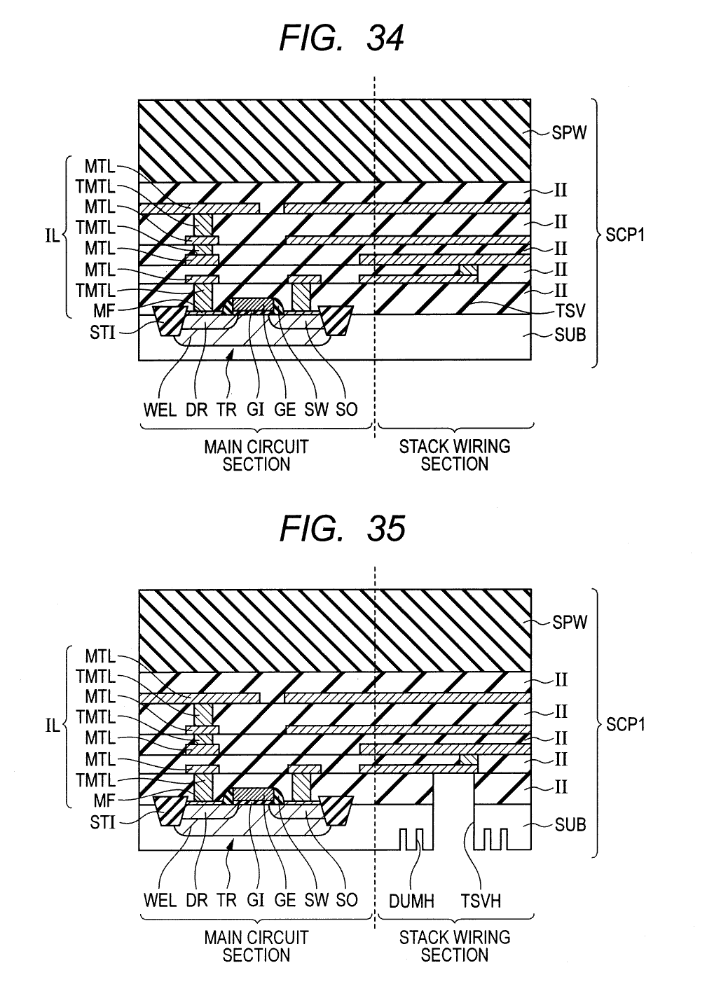

The steps shown in FIGS. 33 and 34 are the same as the steps shown in FIGS. 14 and 15 in the first embodiment. Referring to FIG. 35, a conductive via hole TSVH and dummy via holes DUMH are formed in a stacked wiring section. This step corresponds to the step shown in FIG. 16 in the first embodiment. In this second embodiment, however, the conductive via hole TSVH is formed shallower than in the first embodiment. More specifically, the conductive via hole TSVH is formed so that the bottom wall surface thereof reaches a metal wiring MTS in a lower layer portion of the wiring layer IL.

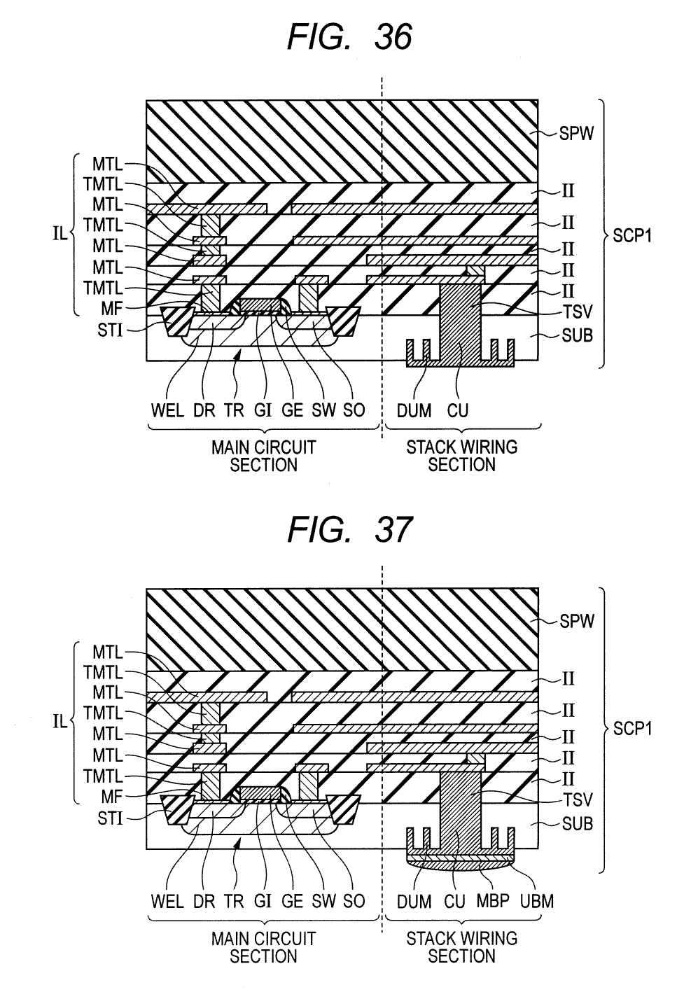

In the above points this second embodiment is different from the first embodiment. The subsequent steps, i.e., the steps shown in FIGS. 36 to 39 are the same as the steps shown in FIGS. 17 to 20 in the first embodiment.

In this second embodiment, the conductive via TSV is formed so as to provide an electrical coupling between a metal wiring MTL in the semiconductor chip SCP1 and for example a pad electrode PAD in the second semiconductor chip SCP2. On the other hand, in the first embodiment, the conductive via TSV is formed so as to provide an electrical coupling between a pad electrode PAD in the semiconductor chip SCP1 and a pad electrode PAD in the second semiconductor chip SCP2.

Also in this second embodiment there basically is obtained the same effect as in the first embodiment. That is, with the dummy via holes DUMH formed around each conductive via hole TSVH, the filling of the conductor CU to the interior of the conductive via hole TSVH is done in higher efficiency and in higher quality.

This second embodiment is different from the first embodiment in only the points described above. Other configurations, conditions, procedures and effects than those described above in the second embodiment are all the same as in the first embodiment.

### Third Embodiment

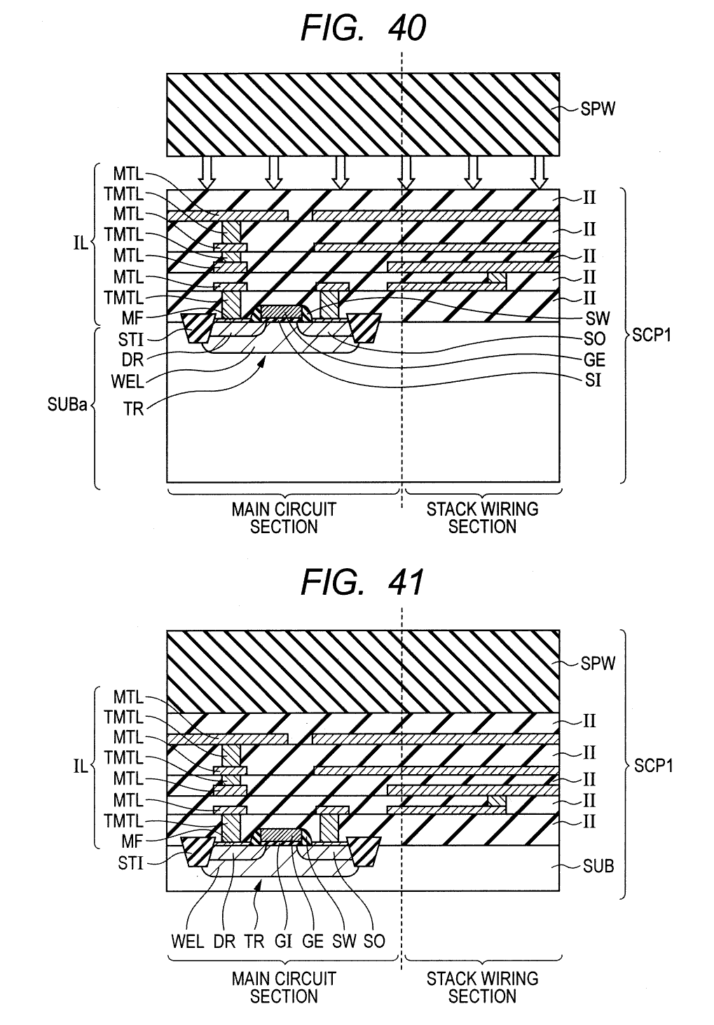

This third embodiment is different from the first embodiment in the method for stacking semiconductor chips SCP. A description will be given below about a method for fabricating a stacked structure of plural semiconductor chips in this third embodiment with reference to FIGS. 40 to 46.

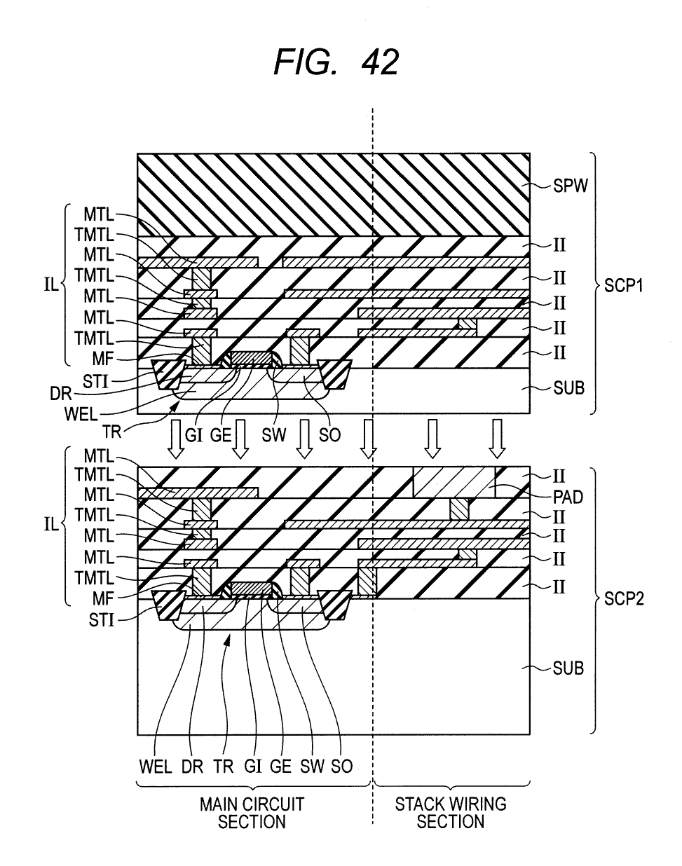

The steps shown in FIGS. 40 and 41 are the same as the steps shown in FIGS. 14 and 15 in the first embodiment. Referring to FIG. 42, semiconductor chips SCP1 and SCP2 are stacked. In this case, for fixing both semiconductor chips SCP1 and SCP2 to each other there may be used for example the same microbumps MBP as in the first embodiment or there may be adopted any other known method, for example, using epoxy resin as an adhesive.

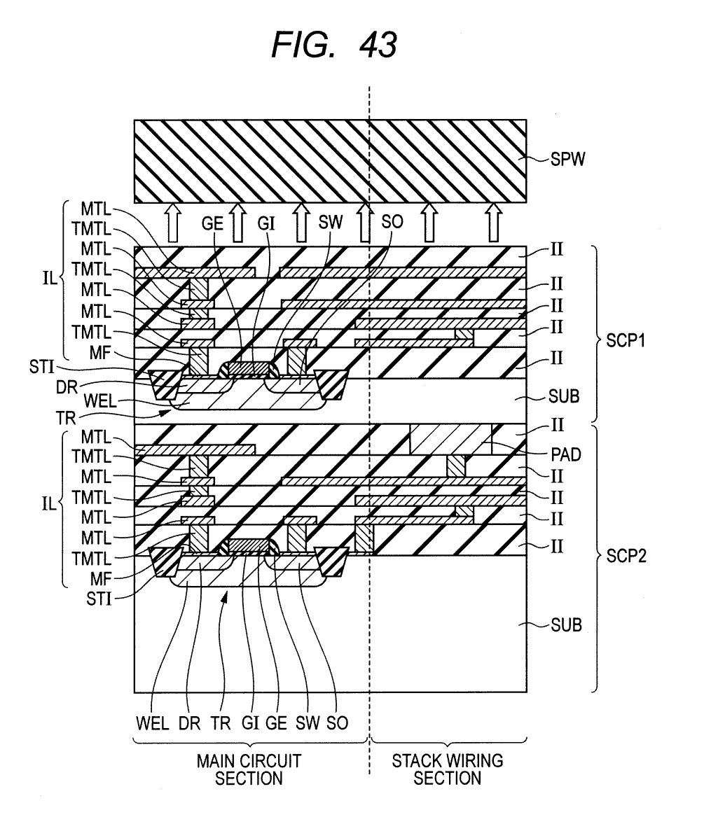

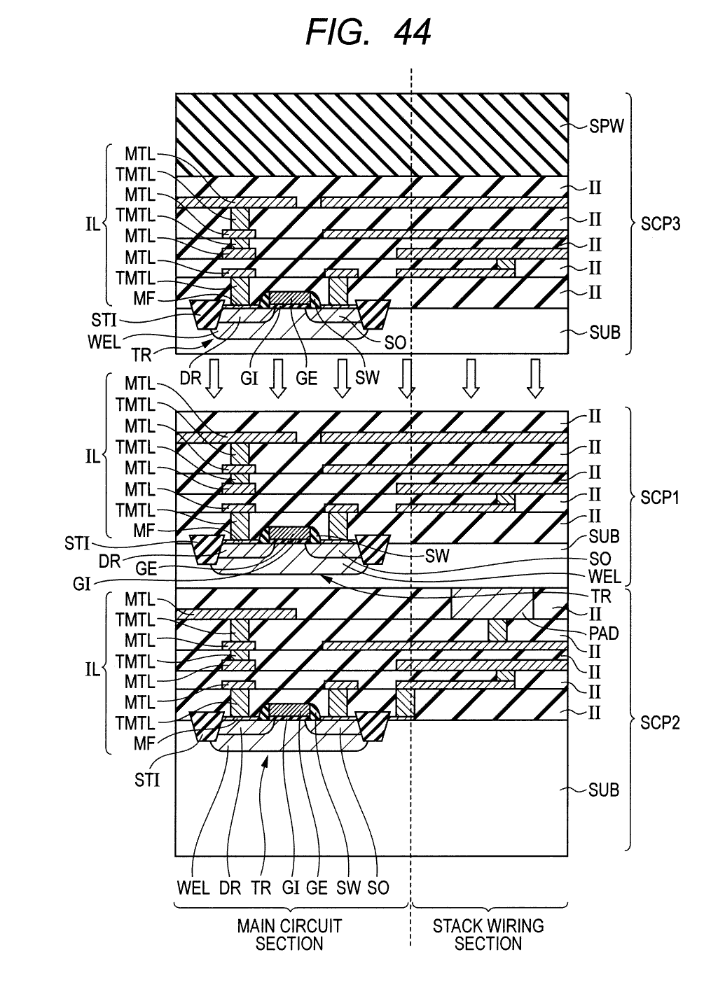

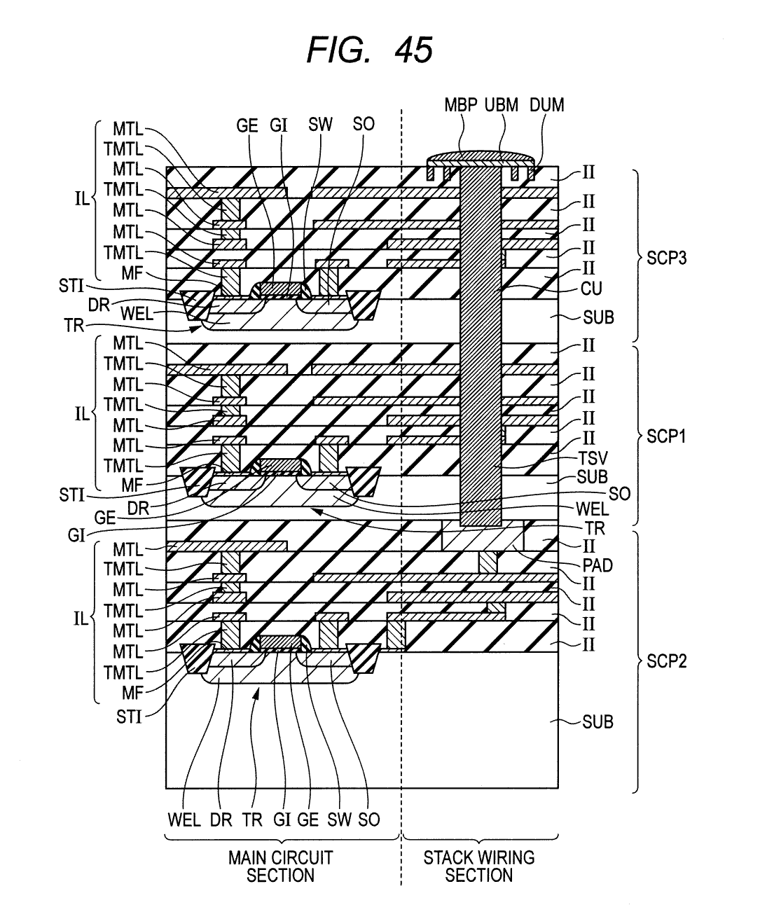

Referring to FIG. 43, a supporting substrate SPW is removed in the same way as in the step of FIG. 20 in the first embodiment. Referring to FIG. 44, a semiconductor chip SCP3 is further stacked on the semiconductor chip SCP1. The semiconductor chip SCP3 is a semiconductor substrate of the same configuration as the semiconductor chips SCP1 and SCP2 for example. Also as to the fixing of the semiconductor chip SCP3 to the semiconductor chip SCP1, it is done by the same method as in FIG. 42.

Referring to FIG. 45, a conductive via TSV extending downwards from the top surface of the semiconductor chip SCP3 and reaching a pad electrode PAD of the semiconductor chip SCP2 through the semiconductor chip SCP1, as well as dummy vias DUM, are formed. The conductive via TSV and dummy vias DUM are formed in accordance with the same procedure as in FIGS. 16, 17 and FIGS. 22 to 30 in the first embodiment.

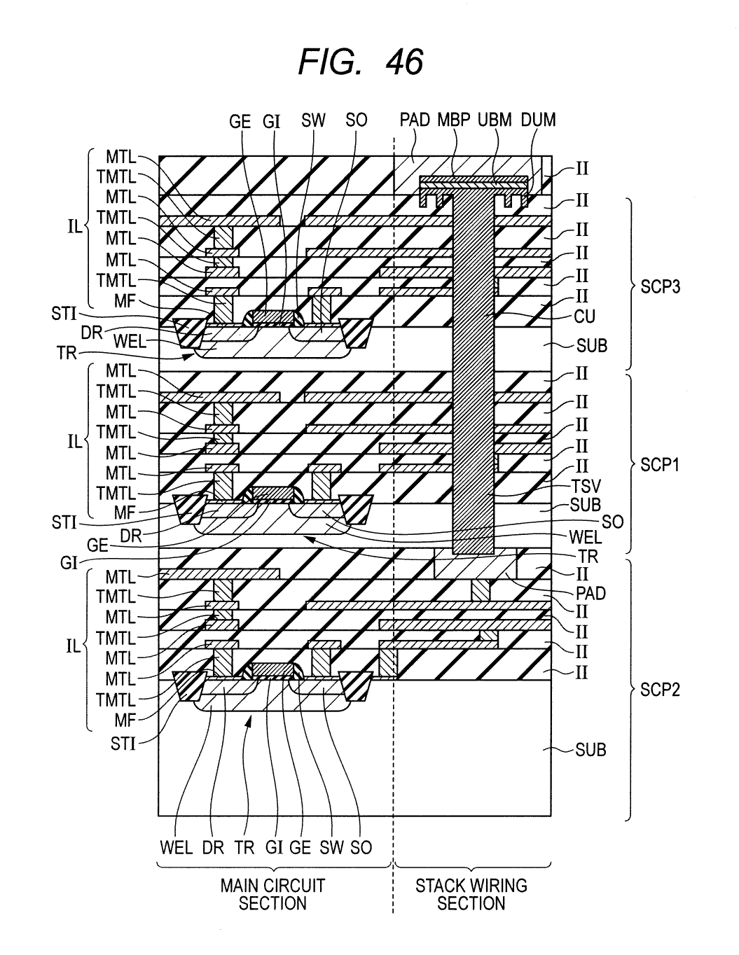

Referring to FIG. 46, a pad electrode PAD is formed on the top surface (a surface corresponding to end portions of the conductive via TSV and dummy vias DUM) of the semiconductor chip SCP3 and the pad electrode PAD and the conductive via TSV are coupled together electrically. By this procedure, the semiconductor chip SCP3 and the semiconductor chip SCP2 located two layers below are coupled together electrically through the conductive via TSV.

Thus, the conductive via TSV may be formed so as to extend through plural semiconductor chips SCP. For example, although in FIG. 46 three semiconductor chips SCP are stacked, also in the case where four or more semiconductor chips SCP are stacked, the top and bottom semiconductor chips SCP can be coupled together electrically through the conductive via TSV.

In this third embodiment the conductive via TSV is formed after stacking plural semiconductor chips SCP. In this point the third embodiment is different from the first and second embodiments wherein the conductive via TSV is formed before stacking plural semiconductor chips SCP. Also in this third embodiment the filling of the conductor CU to the interior of the conductive via TSV is done positively by the dummy vias DUM formed around the conductive via TSV.

In all of the manufacturing methods according to the first to third embodiments conductive vias TSV are formed after formation of transistors TR. For example, in case of forming conductive vias TSV before formation of transistors TR, it is preferable that the conductor to be filled in the interior of each conductive via TSV be a conductive material other than copper.

In the case where conductive vias TSV are formed before formation of transistors TR, the copper present in the interior of each conductive via is diffused for example in the step of thinning the substrate SUB including the conductive vias TSV. In this case, there is the possibility that the diffused copper may exert a bad influence on the transistors TR which are formed subsequently. Further, there is the possibility that the conductive vias TSV formed of copper may be damaged in heat treatment for forming transistors TR and impair the function as the conductive vias TSV. Thus, in case of forming conductive vias TSV before formation of transistors TR, it is preferable that the conductor to be filled in the interior of each conductive via TSV be a conductive material other than copper.

In only the above point this third embodiment is different from the first embodiment. That is, the configurations, conditions, procedures and effects not referred to above in the third embodiment are all the same as in the first embodiment.

A semiconductor device according to the present invention may be configured by suitably combining the above embodiments. Also in this case it is possible to obtain the same effects as those described in the respective embodiments. It should be considered that the embodiments disclosed above are illustrative, not limitative, in all the points. It is contemplated that the scope of the present invention is defined not by the above description but by the scope of claims and that all changes made in the meaning and scope equivalent to the scope of claims are included in the scope of the present invention.

The present invention is applicable advantageously to semiconductor devices having a multi-layer interconnection structure.

What is claimed is:

1. A semiconductor device having a plurality of stacked semiconductor substrates, the semiconductor substrates comprising a first semiconductor substrate and a second semiconductor substrate,
wherein the first semiconductor substrate comprises:
a substrate having main surfaces;
a first semiconductor element formed within and over the substrate;
a first wiring coupled to the first semiconductor element electrically; and
a conductive layer formed in the interior of a through hole extending through mutually confronting first and second main surfaces as the main surfaces of the substrate and reaching the first wiring,
wherein the second semiconductor substrate is stacked directly over the first semiconductor substrate, and comprises:
a second semiconductor element; and
a second wiring,
wherein the conductive layer is coupled to the second wiring of the second semiconductor substrate electrically,
wherein a recess is formed around an end portion of the through hole,
wherein a bottom wall surface of the recess is present in the interior of the substrate, and
wherein a conductive material which forms the conductive layer is filled in the interior of the recess.

2. A semiconductor device according to claim 1, wherein the conductive layer and the conductive material filled in the interior of the recess are coupled together electrically.

3. A semiconductor device according to claim 1 or claim 2, wherein an end portion of the conductive layer and the recess have a planar shape of point symmetry centered on a central part of the end portion of the conductive layer.

4. A semiconductor device according to any of claims 1 to 3, wherein the recess is disposed at a position of point symmetry with respect to the conductive layer.

5. A semiconductor device according to any of claims 1 to 4, wherein the conductive layer and the second wiring of the second semiconductor substrate are coupled together electrically by a microbump.

6. A semiconductor device according to claim 5, wherein the microbump covers the whole surface of the recess and the end portion of the conductive layer.

7. A semiconductor device according to any of claims 1 to 6, wherein the first semiconductor substrate has a multi-layer interconnection.

8. A method for manufacturing a semiconductor device, comprising the steps of:
providing a first semiconductor substrate including a substrate having main surfaces, a first semiconductor element formed within and over the substrate, and a first wiring coupled to the first semiconductor element electrically;
forming a through hole and a recess, the through hole extending through mutually confronting first and second main surfaces as the main surfaces of the substrate and reaching the first wiring, and the recess being around one end portion of the through hole provided in the second main surface;
forming a conductive layer to fill the interior of the through hole and that of the recess;
providing a second semiconductor substrate having a second semiconductor element and a second wiring;
stacking the first and second semiconductor substrates one over the other; and
coupling the conductive layer and the second wiring of the second semiconductor substrate with each other electrically,
wherein a bottom wall surface of the recess is present in the interior of the substrate.

9. A method according to claim 8, wherein the step of forming the through hole and the recess is performed before the stacking step.

10. A method according to claim 8, wherein the step of forming the through hole and the recess is performed after the stacking step.
